(19) United States
(12) Patent Application Publication
(10) Pub. No.: US 2025/0167081 A1
(43) Pub. Date: May 22, 2025

(54) REVERSIBLE POWER MODULE AND A PROCESS OF IMPLEMENTING A REVERSIBLE POWER MODULE

(71) Applicant: Wolfspeed, Inc., Durham, NC (US)

(72) Inventors: Ajit R. Kanale, Morrisville, NC (US); Prasanna Obala Bhuvanesh, Leander, TX (US); Brice McPherson, Fayetteville, AR (US); Paul Wheeler, Allen, TX (US)

(21) Appl. No.: 18/518,105

(22) Filed: Nov. 22, 2023

(51) Int. Cl. H01L 23/495; H01L 23/498; H01L 23/538; H01L 25/11

(52) U.S. Cl. CPC H01L 23/49562; H01L 23/49575; H01L 23/49811; H01L 23/5386; H01L 25/115

(57) ABSTRACT

A power package includes an assembly having a first power package side and a second power package side; first power terminals arranged at the first power package side; second power terminals arranged at the second power package side; first signal terminals arranged at the first power package side; and second signal terminals arranged at the second power package side. Additionally, locations of the first power terminals and the second power terminals are symmetrical and/or locations of the first signal terminals and the second signal terminals are symmetrical.

### FIELD OF THE DISCLOSURE

The disclosure relates to a reversible power module. The disclosure further relates to a process of implementing a reversible power module.

### BACKGROUND OF THE DISCLOSURE

As will be appreciated by those skilled in the art, power modules are known in various forms. Power modules provide a physical containment for power components, usually power semiconductor devices. These power semiconductors are typically soldered or sintered on a power electronic substrate. The power module typically carries the power semiconductors, provides electrical and thermal contact, and includes electrical insulation. However, a configuration of power modules typically limits implementations of the power module.

Accordingly, a power module having an improved configuration is needed.

### SUMMARY OF THE DISCLOSURE

The foregoing needs are met, to a great extent, by the disclosure, wherein a reversible power module and a process of implementing a reversible power module are provided.

In one aspect, a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where a location of the first power terminals on the first power package side is symmetrical with respect to a location of the second power terminals on the second power package side.

In one aspect, a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where a location of the first signal terminals on the first power package side is symmetrical with respect to a location of the second signal terminals on the second power package side.

In one aspect, a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where a location of the first signal terminals on the first power package side is symmetrical with respect to one side of the first power package side and another side of the first power package side. The power package furthermore includes where a location of the second signal terminals on the second power package side is symmetrical with respect to one side of the second power package side and another side of the second power package side.

In one aspect, a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where a location of the first signal terminals on the first power package side is symmetrical with respect to a location of the second signal terminals on the second power package side.

In one aspect, a process includes providing an assembly with a first power package side and a second power package side. The process also includes arranging first power terminals at the first power package side. The process furthermore includes arranging second power terminals at the second power package side. The process in addition includes arranging first signal terminals at the first power package side. The process moreover includes arranging second signal terminals arranged at the second power package side. The process also includes where a location of the first power terminals on the first power package side is symmetrical with respect to a location of the second power terminals on the second power package side.

In one aspect, a process includes providing an assembly with a first power package side and a second power package side. The process also includes arranging first power terminals at the first power package side. The process furthermore includes arranging second power terminals at the second power package side. The process in addition includes arranging first signal terminals at the first power package side. The process moreover includes arranging second signal terminals arranged at the second power package side. The process also includes where a location of the first power terminals on the first power package side is symmetrical with respect to one side of the first power package side and another side of the first power package side. The process furthermore includes where a location of the second power terminals on the second power package side is symmetrical with respect to one side of the second power package side and another side of the second power package side.

In one aspect, a process includes providing an assembly with a first power package side and a second power package side. The process also includes arranging first power terminals at the first power package side. The process furthermore includes arranging second power terminals at the second power package side. The process in addition includes arranging first signal terminals at the first power package side. The process moreover includes arranging second signal terminals arranged at the second power package side. The process also includes where a location of the first signal terminals on the first power package side is symmetrical with respect to one side of the first power package side and another side of the first power package side. The process furthermore includes where a location of the second signal terminals on the second power package side is symmetrical with respect to one side of the second power package side and another side of the second power package side.

In one aspect, a process includes providing an assembly with a first power package side and a second power package side. The process also includes arranging first power terminals at the first power package side. The process furthermore includes arranging second power terminals at the second power package side. The process in addition includes arranging first signal terminals at the first power package side. The process moreover includes arranging second signal terminals arranged at the second power package side. The process also includes where a location of the first signal terminals on the first power package side is symmetrical with respect to a location of the second signal terminals on the second power package side.

In one aspect, a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where an arrangement and location of the first power terminals is symmetrical about a lateral axis of symmetry with respect to an arrangement and location of the second power terminals.

In one aspect, a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where an arrangement and location of the first power terminals is symmetrical about a longitudinal axis of symmetry with respect to an arrangement and location of the second power terminals.

In one aspect, a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where an arrangement and location of the first signal terminals is symmetrical about a longitudinal axis of symmetry with respect to an arrangement and location of the second signal terminals.

In one aspect, a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where an arrangement and location of the first signal terminals is symmetrical about a lateral axis of symmetry with respect to an arrangement and location of the second signal terminals.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates top views of a power module according to aspects of the disclosure.

FIG. 2 illustrates top views of another configuration of a power module according to aspects of the disclosure.

FIG. 3 illustrates top schematic view of the power module according to aspects of the disclosure.

FIG. 4 illustrates a top view of an exemplary implementation power module according to aspects of the disclosure.

FIG. 5 illustrates top views of the power module of FIG. 4 prior to reversal and after reversal.

FIG. 6 illustrates a top view of the power module according to FIG. 4 after being reversed.

FIG. 7 illustrates a top view of a power module according to aspects of the disclosure.

FIG. 8 illustrates a top view of the power module according to FIG. 7 after being reversed.

FIG. 9 illustrates a partial perspective view of an exemplary implementation a power module according to aspects of the disclosure.

FIG. 10 illustrates a further partial perspective view of the exemplary implementation the power module according to FIG. 9.

FIG. 11 illustrates a further partial perspective view of the exemplary implementation the power module according to FIG. 9.

FIG. 12 illustrates a perspective view of the exemplary implementation the power module according to FIG. 9.

FIG. 13 illustrates another partial perspective view of the exemplary implementation the power module according to FIG. 9.

FIG. 14 illustrates is schematic of the power module 100 according to aspects of the disclosure.

FIG. 15 illustrates a partial side view of the power module according to aspects of the disclosure.

FIG. 16 illustrates a further partial side view of the power module according to FIG. 15.

FIG. 17 illustrates an end view of the first power module side of the power module according to aspects of the disclosure.

FIG. 18 illustrates an end view of the second power module side of the power module according to aspects of the disclosure.

FIG. 19 illustrates a partial perspective view of an exemplary implementation a power module according to aspects of the disclosure.

FIG. 20 illustrates a further partial perspective view of the exemplary implementation the power module according to FIG. 19.

FIG. 21 illustrates a further partial perspective view of the exemplary implementation the power module according to FIG. 19.

FIG. 22 illustrates a partial perspective view of an exemplary implementation a power module according to aspects of the disclosure.

FIG. 23 illustrates a further partial perspective view of the exemplary implementation the power module according to FIG. 22.

FIG. 24 illustrates a further partial perspective view of the exemplary implementation the power module according to FIG. 22.

FIG. 25 illustrates a further partial perspective view of the exemplary implementation the power module according to FIG. 22.

FIG. 26 illustrates a further partial perspective view of the exemplary implementation the power module according to FIG. 22.

FIG. 27 illustrates a partial perspective view of an exemplary implementation a power module according to aspects of the disclosure.

FIG. 28 illustrates a further partial perspective view of the exemplary implementation the power module according to FIG. 27.

FIG. 29 illustrates a further partial perspective view of the exemplary implementation the power module according to FIG. 27.

FIG. 30 illustrates a partial perspective view of an exemplary implementation a power module according to aspects of the disclosure.

FIG. 31 illustrates a further partial perspective view of the exemplary implementation the power module according to FIG. 30.

FIG. 32 illustrates a power module implemented with a plurality of power module portions according to aspects of the disclosure.

FIG. 33 illustrates an exemplary implementation of the power module of FIG. 32.

FIG. 34 illustrates another exemplary implementation of the power module of FIG. 32.

### DETAILED DESCRIPTION

The disclosure will now be described with reference to the drawing figures, in which like reference numerals refer to like parts throughout. Aspects of the disclosure advantageously provide a reversible power module and a process of implementing a reversible power module.

The structures and techniques described in this disclosure describe a power module with paralleled power semiconductors. With a rise in interest in back-to-back bidirectional switches for high-power applications, the disclosed power module can be used in a variety of topologies including standalone, paralleled, common-source bidirectional, common-drain bidirectional, and/or the like.

The disclosure details this modular and reversible package and/or power module that allows for significant amounts of modularity and scalability. The power module may be scaled to match industry standard footprints to be compatible with series, parallel, common-source, common-drain, and/or the like interconnections.

Aspects of the disclosed power module are configured such that a layout and structure of a high-current symmetric pin-out single switch position power module may be implemented in common-source or common-drain connections externally; a layout and structure of a high-current symmetric pin-out multi switch position power module may have a common-source, a common-drain, and/or the like connection internally; a layout and structure that may be compatible with multiple internal interconnection methods, such as one or more wire bonds, ribbons, clips, and/or the like; a layout and structure that may be compatible with single sided, double sided cooling, and/or the like; terminal arrangements that may include signal pins on the inside and power pins on the outside; terminal arrangements with power pins on the inside and signal pins on the outside; terminal arrangements with interleaved power and signal pins; terminal structures that may enhance end to end interconnection with strain relief; a modular layout which may house multiple device types, devices sizes, physical arrangements, and/or the like; a scalable structure such that a length and a width may be configured to adapt to a given size to meet footprint requirements, to optimize power density, and/or the like; a scalable structure such that a length and a width can be configured to adapt to optimize heat spreading, thermal performance, and/or the like; a layout and structure configured to implement additional functionality such as temperature sensors, current sensors, strain sensors, and/or the like; and a structure configured to be compatible with multiple power module implementations, including a case module with or without base plate, an over molded module with or without base plate, and/or the like.

Aspects of the disclosed power module are configured to implement techniques for realizing a common-source, a common-drain, and/or the like bidirectional switch topologies with the single switch module; and techniques for paralleling the common-source and common-drain modules.

Aspects of the disclosure may be configured such that in many applications, power modules may be used with a relatively small number of power devices, such as one to four power devices. These power modules can then be used as building blocks to scale up or down to the desired output current and/or the like. Thereafter, the power modules may be arranged to form the desired topology. For example, six single switch packages could be arranged to form a three-phase topology that may implement three bridge legs. If twice the output power is desired, twelve packages may be arranged to form the same topology with paralleled packages for each bridge leg.

This high level of modularity allows customers with a variety of end use power levels and applications to adopt the same module for all of their systems. Often, however, this comes at the cost of system complexity due to the number of parts, and reduced power density due to placement and tolerance.

The modular and scalable reversible module of the disclosure may be configured to have the capability to meet the needs of many applications in a way that can be compact and maintain the flexibility of multiple package approaches, while also being able to scale up to house a large number of power devices in a single housing. Further, the modular and scalable reversible module of the disclosure may also be configured to form a topology, or arrangement of devices, in a manner best suited for the target application.

As described and illustrated herein, one example terminal arrangement may have a symmetrical pinout. In aspects, the pins may be identical on either side of the power module. In aspects, this may allow for the power modules to the placed end to end to scale up to a given power level, to allow for interconnection to form a topology, and/or the like. Other terminal arrangements are possible, with the opposite side matching for symmetry.

As described and illustrated herein, the power module may be configured with numerous devices, such as twelve devices for each switch position, in two symmetrical rows. The power devices may be paralleled. Moreover, connection leads may be placed in a symmetric manner. The number of devices may be increased or decreased internally, or the packages could be readily paralleled externally. This symmetry may allow for the power module to cater to multiple applications.

As described and illustrated herein, the power module may be configured with physical arrangements to form topologies for the reversible module. As an example, commercial electrical vehicle manufacturers may use standalone or paralleled power modules in high-power applications such traction motor drives, onboard battery chargers, and/or the like. These power modules might require unidirectional or bidirectional current flow capabilities, depending on the topology.

As another example three level inverter topologies such a T-Type inverter may allow for less distortion of the output current requiring less filtering to achieve a clean output signal. A reversible module as described and illustrated herein, may be utilized in all the aforementioned topologies. For example, a power module with a common-source, a common-drain, and/or like connections being made external to the power module as needed. In aspects, a symmetry in the external leads of the power module may lend itself to easier connections. Accordingly, the power modules when connected in a bidirectional topology would be able to block voltages and conduct currents in both directions, while maintaining low on-resistance and maximizing efficiency.

In aspects, the power modules and/or power packages as disclosed may house multiple three terminal power devices, such as MOSFETs, JFETs, IGBTs, and/or the like in which there are two power terminals and a gate terminal per power device. For each power device, there are two critical electrical loops associated with a function of the power device. The power loop may be where high current flows from one terminal, such as a drain, a collector, and/or the like to the other terminal, such as a source, an emitter, and/or the like. The signal loop may be configured for controlling a signal current flow from the gate to the appropriate terminal, such as a source, an emitter, as lessor the like.

In the disclosed implementation of a reversible module, the power loop may be from the drain lead to the source lead. There may be two signal loops for each device, each from their individual gates to the common source node. Depending on how the device will be used, the importance of the signal loop must be considered. For a circuit breaker, the associated devices may be running in the on-state for the majority of the operational time. Here, switching efficiency and quality may be less significant. Hence, the power loop impedance may be less significant. However, in a switching application, such as in an inverter, switching events may occur often so efficiency and quality may be of high importance, with an according importance in the power loop impedance.

In aspects, the power modules and/or power packages as disclosed may be configured such that drain-source (or collector-emitter) and gate-source (or gate-emitter) loops may share a same connection at the source (or emitter) of the power module. If the power path couples into the signal paths, extra dynamics may be introduced through either positive or negative feedback. Typically, negative feedback may introduce extra losses as the power path coupling fights the control signal (i.e. the power path coupling tries to turn the device off when the control signal is trying to turn the device on). Positive feedback typically causes instability as the power path coupling amplifies the control signal until the devices are destroyed. Ultimately, the coupling of power and signal paths may result in a reduction in switching quality, slower switching speeds, increased losses, and possible destruction.

Accordingly, aspects of the disclosed power module may be configured to improve switching quality and may implement independent loops. Here, the power source connection may have a separate path from the signal source (referred to as a Kelvin source) such that one does not overlap or interfere with the other. The closer the separate connections are made to the device, the better the switching performance may be.

Accordingly, aspects of the disclosed power module may be configured such that the loops may be completely independent, this is referred as a ‘true kelvin’ connection. This may be achieved with symmetrical layouts by having additional pins for the signals such that the module can be rotated 180 degrees and the neighboring pins match the same pinout. If a pin is in the middle of the module, it does not need to be duplicated.

Accordingly, aspects of the disclosed power module may be configured such that a presence of external leads for all terminals can be leveraged to realize common-source and/or common-drain connections for various applications. The presence of external leads can be employed to access the common node for purposes of protection circuitry such as DESAT, a current shunt, a Rogowski coil, and/or the like.

Accordingly, aspects of the disclosed power module may be configured as a universal module, which provides paralleled die in a single housing with completely symmetric power and signal loop pins. In aspects, an advantage of the disclosed power module configuration is that the power module may be used as a single switch or coupled with other such modules to realize common-source and/or common-drain topology. Furthermore, as required by applications, the disclosed power modules may be connected in series and/or paralleled. In aspects, a single footprint implementation of the power module for all the above mentioned circuit options may result in a power module that can be used ubiquitously.

Aspects of the disclosed power module may be encapsulated through over molding or using other materials such as ceramic frames with silica gel, epoxy-resin, etc. Aspects of the disclosed power module may include staggered pinouts and/or terminals that may enable easy series/parallel connection of modules.

Aspects of the disclosed power module may: include implementations with single-side cooled module topologies; wide power ribbons configured with horizontal fanout around outer border; narrow signal ribbons configured with vertical fanout along central line; one or more metallic clips connecting to a power source to reduce wire bonds; configured to be Scalable in size and accommodate multiple chips of various sizes, shapes; as a single switch that may be connected externally in various topologies such as—series topologies, parallel topologies, anti-series topologies, common-source topologies, common-drain topologies, and/or the like; and/or configured to adopt various applications including switching intensive applications, normally-on applications, and/or the like.

Aspects of the disclosed power module may: be configured with power terminals arranged along outer border and signal pinouts along center; be configured with vertically staggered ribbons for easy module interconnection; implement metallic clips for connecting power source to reduce wire bonds; the configured to be scalable in size and accommodate multiple chips of various sizes, shapes; configured as a single switch that may be connected externally in various topologies—series topologies, parallel topologies, anti-series topologies, common-source topologies, common-drain topologies, and/or the like; and/or be configured to adopt for various applications including switching intensive applications, normally-on applications, as lessor the like.

Aspects of the disclosed power module may: configured with a common-source bidirectional switch topology; configured with a split drain pad that allows grouping devices into common-drain topology; configured such that all devices may be driven through the gate signal in the center rail; configured with narrow signal ribbons implementing a vertical fanout along central line; configured with metallic clips connecting power source to reduce wire bonds; configured such that a number of devices may be adjusted to cater to different power ratings; and/or configured with two gate signal rails in the center and two bidirectional switches that can be functionally separated.

Aspects of the disclosed power module may: configured with a common-source bidirectional switch topology; configured with vertically staggered ribbons for easy module interconnection; configured such that all devices driven through the gate signal in the center rail; configured with narrow signal ribbons having a vertical fanout along central line; configured with metallic clips connecting power source to reduce wire bonds; configured with a number of devices that may be adjusted to cater to different power ratings; and/or configured with two gate signal rails in the center and two bidirectional switches that may be functionally separated.

Aspects of the disclosed power module may: configured as a common-drain bidirectional switch; configured with narrow signal ribbons implementing vertical fanout along central line; configured with metallic clips connecting a power source to reduce wire bonds; configured such that a number of devices may be adjusted to cater to different power ratings; configured with two gate signal rails in the center and two bidirectional switches can be functionally separated.

Aspects of the disclosed power module may: be configured as a common-drain bidirectional switch; configured with vertically staggered ribbons for easy module interconnection; configured with narrow signal ribbons having a vertical fanout along central line; configured with metallic clips connecting to a power source to reduce wire bonds; configured such that a number of devices may be adjusted to cater to different power ratings; and/or configured with two gate signal rails in the center and two bidirectional switches that may be functionally separated.

Aspects of the disclosed power module may: be configured as a common- and source bidirectional switch; configured with narrow signal pins around outer border; configured with wide power pins in the center; configured with metallic clips connecting power source to reduce wire bonds; configured so as to be scalable in size and accommodate multiple chips of various sizes, shapes; and/or configured as a single symmetric common-source switch.

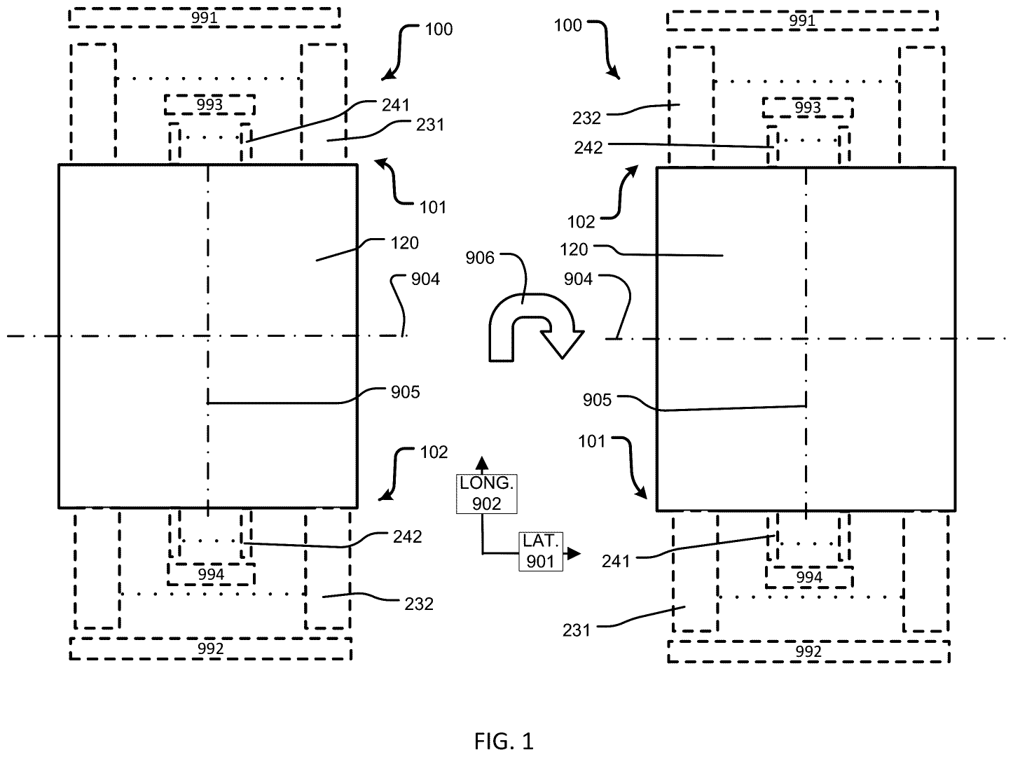

FIG. 1 illustrates top views of a power module according to aspects of the disclosure.

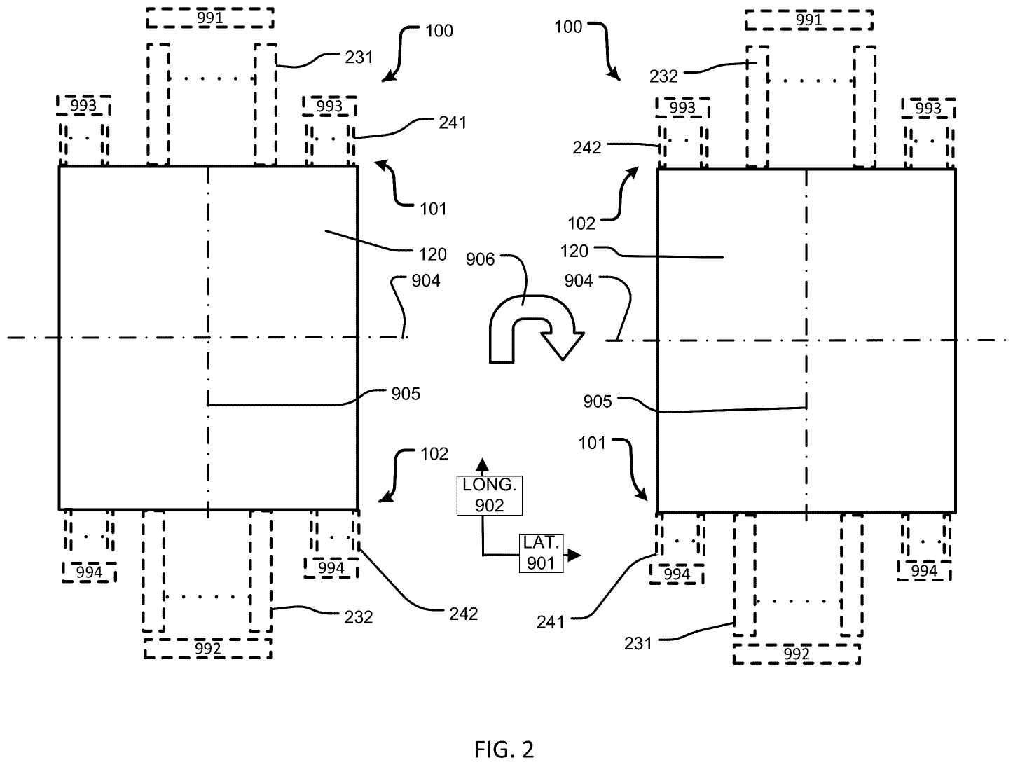

FIG. 2 illustrates top views of another configuration of a power module according to aspects of the disclosure.

In particular, FIG. 1 illustrates top views of a power module 100 according to aspects of the disclosure prior to reversal of the power module 100 and after reversal of the power module 100; and FIG. 2 illustrates top views of another implementation of the power module 100 according to aspects of the disclosure prior to reversal of the power module 100 and after reversal of the power module 100. In aspects, the power module 100 may be implemented as a power module, a power package, a reversible power module, a reversible power package, and/or the like.

In aspects, the power module 100 may include an assembly 120, first power terminals 231, second power terminals 232, first signal terminals 241, second signal terminals 242, and/or the like.

The assembly 120 may include a first power module side 101 and a second power module side 102. The first power module side 101 and the second power module side 102 may be arranged on opposing sides of the assembly 120 and/or the power module 100. In aspects, the first power module side 101 and the second power module side 102 may be arranged parallel to a lateral axis 901 of the power module 100 as illustrated in FIG. 1.

In aspects, the first power terminals 231 may be arranged at the first power module side 101 of the power module 100; and the second power terminals 232 may be arranged at the second power module side 102 of the power module 100. In aspects, the first power terminals 231 may extend along a longitudinal axis 902 from the first power module side 101. In aspects, the second power terminals 232 may extend along a longitudinal axis 902 from the second power module side 102.

Further, the first power terminals 231 may connect to respective first power connections 991 of an application (illustrated schematically); and the second power terminals 232 may connect to respective second power connections 992 of an application (illustrated schematically).

In aspects, the first signal terminals 241 may be arranged at the first power module side 101; and the second signal terminals 242 may be arranged at the second power module side 102. In aspects, the first signal terminals 241 may extend along the longitudinal axis 902 from the first power module side 101. In aspects, the second signal terminals 242 may extend along the longitudinal axis 902 from the second power module side 102.

Further, the first signal terminals 241 may connect to respective first signal connections 993 to an application (illustrated schematically); and the second signal terminals 242 may connect to respective second signal connections 994 to an application (illustrated schematically).

In aspects as disclosed herein, the power module 100 may be configured as a reversible power module, a reversible power package, and/or the like such that the power module 100 may be repositioned or reoriented, such as by rotation about an axis perpendicular to the lateral axis 901 and the longitudinal axis 902. More specifically, a reversible power module, a reversible power package, and/or the like as disclosed herein may be an implementation of the power module 100 configured to allow a physical positioning and/or orientation of the power module 100 to be reversed or reoriented and provide commensurate operation of the power module 100. In other words, the power module 100 is configured to provide a same operating capabilities, functionalities, and/or the like independent of an orientation of the power module 100.

In aspects, an arrangement and location of the first power terminals 231 on the first power module side 101 may be symmetrical with respect to an arrangement and location the second power terminals 232 on the second power module side 102.

In aspects, the power module 100 may have a lateral axis of symmetry 904. In aspects, an arrangement and location of the first power terminals 231 may be symmetrical about the lateral axis of symmetry 904 with respect to an arrangement and location the second power terminals 232.

In aspects, an arrangement and location of the first signal terminals 241 on the first power module side 101 may be symmetrical with respect to an arrangement and location the second signal terminals 242 on the second power module side 102.

In aspects, an arrangement and location of the first signal terminals 241 may be symmetrical about the lateral axis of symmetry 904 with respect to an arrangement and location the second signal terminals 242.

In aspects, an arrangement and location of the first power terminals 231 on the first power module side 101 may be symmetrical with respect to one side of the first power module side 101 and another side of the first power module side 101. In aspects, and arrangement and location the second power terminals 232 on the second power module side 102 may be symmetrical with respect to one side of the second power module side 102 and another side of the second power module side 102.

In aspects, the power module 100 may have a longitudinal axis of symmetry 905. In aspects, an arrangement and location of the first power terminals 231 may be symmetrical about the longitudinal axis of symmetry 905 with respect to an arrangement and location the second power terminals 232.

In aspects, an arrangement and location of the first signal terminals 241 on the first power module side 101 may be symmetrical with respect to one side of the first power module side 101 and another side of the first power module side 101. In aspects, an arrangement and location the second signal terminals 242 on the second power module side 102 may be symmetrical with respect to one side of the second power module side 102 and another side of the second power module side 102.

In aspects, an arrangement and location of the first signal terminals 241 may be symmetrical about the longitudinal axis of symmetry 905 with respect to an arrangement and location the second signal terminals 242.

As illustrated in FIG. 1, a positioning of the power module 100 is illustrated with an initial orientation on a left side of FIG. 1. Thereafter, the power module 100 may be reversed or reoriented as illustrated on a right side of FIG. 1. In particular, arrow 906 illustrates an exemplary movement or reorientation of the power module 100 illustrated on the left side of FIG. 1 to right side of FIG. 1, which results in a reorientation of the power module 100.

In aspects, after reorienting the power module 100, locations of the first power terminals 231 and the second power terminals 232 may be reversed. In particular, the first power terminals 231 may now connect to the respective second power connections 992; and the second power terminals 232 may now connect to the respective first power connections 991.

In this regard, the power module 100 may be configured to operate in a manner when the first power terminals 231 connect to the respective first power connections 991 and the second power terminals 232 connect to the respective second power connections 992 of the application components as implemented by the power module 100 illustrated on the left side of FIG. 1.

Further, the power module 100 may be configured to operate in a same manner when the first power terminals 231 connect to the respective second power connections 992 and the second power terminals 232 connect to the respective first power connections 991 as implemented by the power module 100 illustrated on the right side of FIG. 1.

In aspects, after reorienting the power module 100, locations of the first signal terminals 241 and the second signal terminals 242 may be reversed. In particular, the first signal terminals 241 may now connect to the respective second signal connections 994; and the second signal terminals 242 may now connect to the respective first signal connections 993 as implemented by the power module 100 illustrated on the right side of FIG. 1.

In this regard, the power module 100 may be configured to operate in a manner when the first signal terminals 241 connect to the respective first signal connections 993 and the second signal terminals 242 connect to the respective second signal connections 994 of the application components as illustrated by the power module 100 illustrated on the left side of FIG. 1.

Further, the power module 100 may be configured to operate in a same manner when the first signal terminals 241 connect to the respective second signal connections 994 and the second signal terminals 242 connect to the respective first signal connections 993 as implemented by the power module 100 illustrated on the right side of FIG. 1.

In aspects, the first signal terminals 241 and/or the second signal terminals 242 may include one or more implementations that include one or more Kelvin source terminals, gate terminals, sensor terminals, and/or the like. In aspects, the first signal terminals 241 and/or the second signal terminals 242 may be implemented as sensor terminals. In this regard, the first signal terminals 241 and/or the second signal terminals 242 may connect to one or more temperature sensors, current sensors, strain sensors, and/or the like implemented within the power module 100.

As further illustrated in FIG. 1, the first signal terminals 241 may be arranged on the first power module side 101 between implementations of the first power terminals 231. As further illustrated in FIG. 1, the second signal terminals 242 may be arranged on the second power module side 102 between implementations of the second power terminals 232.

With reference to FIG. 2, the first power terminals 231 may be arranged on the first power module side 101 between implementations of the first signal terminals 241. As further illustrated in FIG. 2, the second power terminals 232 may be arranged on the second power module side 102 between implementations of the second signal terminals 242.

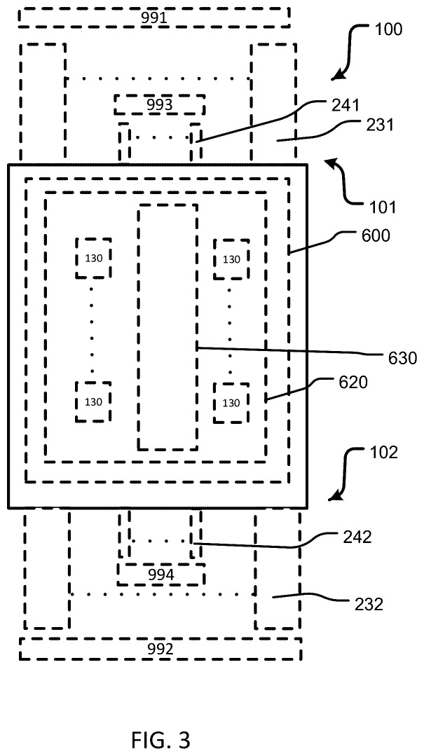

FIG. 3 illustrates top schematic view of the power module according to aspects of the disclosure.

In aspects, the power module 100 may include a power substrate 600, at least one power trace 620 arranged on the power substrate 600 and at least one signal trace 630 arranged on the power substrate 600. In aspects, there may be a plurality of implementations of the at least one power trace 620. In aspects, there may be a plurality of implementations of the at least one power trace 620.

In aspects, the at least one signal trace 630 may include one or more implementations that include Kelvin source traces, gate traces, sensor traces, and/or the like.

In aspects, the at least one power trace 620 may include one or more implementations that include one or more power device drain traces, power device source traces, and/or the like.

Further, the power module 100 may include a plurality of power devices 130 arranged on the power substrate 600. In aspects, the plurality of power devices 130 may be arranged on the at least one power trace 620. In aspects, the plurality of power devices 130 may be arranged on one or more implementations of the at least one power trace 620.

In aspects, the first power terminals 231 and the second power terminals 232 may connect to the at least one power trace 620. In aspects, the first power terminals 231 and the second power terminals 232 may connect to one or more implementations of the at least one power trace 620.

In aspects, the first signal terminals 241 and the second signal terminals 242 may connect to the at least one signal trace 630. In aspects, the first signal terminals 241 and the second signal terminals 242 may connect to one or more implementations of the at least one signal trace 630. In aspects, one of the first signal terminals 241 and/or one of the second signal terminals 242 may be arranged on the longitudinal axis of symmetry 905.

In aspects, an arrangement and location of the plurality of power devices 130, the at least one signal trace 630, the at least one power trace 620, the power substrate 600, and/or the like of power module 100 may be symmetrical about the lateral axis of symmetry 904.

In aspects, an arrangement and location of the plurality of power devices 130, the at least one signal trace 630, the at least one power trace 620, the power substrate 600, and/or the like of power module 100 may be symmetrical about the longitudinal axis of symmetry 905.

In aspects, the plurality of power devices 130, the at least one signal trace 630, the at least one power trace 620, the power substrate 600, and/or the like of power module 100 may be configured to operate in a manner when the first power terminals 231 connect to the respective first power connections 991 and the second power terminals 232 connect to the respective second power connections 992 of the application components as implemented by the power module 100 illustrated on the left side of FIG. 1.

Further, the plurality of power devices 130, the at least one signal trace 630, the at least one power trace 620, the power substrate 600, and/or the like of the power module 100 may be configured to operate in a same manner when the first power terminals 231 connect to the respective second power connections 992 and the second power terminals 232 connect to the respective first power connections 991 as implemented by the power module 100 illustrated on the right side of FIG. 1.

In aspects, one or more of the first power terminals 231, the second power terminals 232, the first signal terminals 241, the second signal terminals 242, the plurality of power devices 130, the at least one signal trace 630, the at least one power trace 620, the power substrate 600, and/or the like may be configured, structured, arranged, implemented, and/or the like such that the power module 100 may implement a standalone configuration, a paralleled configuration, a common-source bidirectional configuration, a common-drain bidirectional configuration, and/or the like.

The disclosure and figures make reference to certain axes that include the lateral axis 901, the longitudinal axis 902, and the vertical axis 903. In aspects, these axes are meant to describe the structural arrangement, spatial arrangement, and/or the like of various components of the power module 100 and/or features of various components of the power module 100. In aspects, the lateral axis 901 extends along a direction perpendicular to the longitudinal axis 902 and the vertical axis 903; the longitudinal axis 902 extends along a direction perpendicular to the lateral axis 901 and the vertical axis 903; and the vertical axis 903 extends along a direction perpendicular to the lateral axis 901 and the longitudinal axis 902. In aspects, utilization of the lateral axis 901 and the longitudinal axis 902 are not meant to denote that one axis of the power module 100 is longer or shorter than another axis of the power module 100. In aspects, a square implementation of the power module 100 may implement features with respect to the lateral axis 901 and the longitudinal axis 902 as described herein.

Aspects of the power module 100 illustrated in FIG. 1, FIG. 2, and FIG. 3 may optionally include any other features of the power module 100 as described and illustrated herein. Further, aspects of the power module 100 illustrated in FIG. 1, FIG. 2, and FIG. 3 and described therewith may optionally be implemented in any other implementations of the power module 100 as described and illustrated herein.

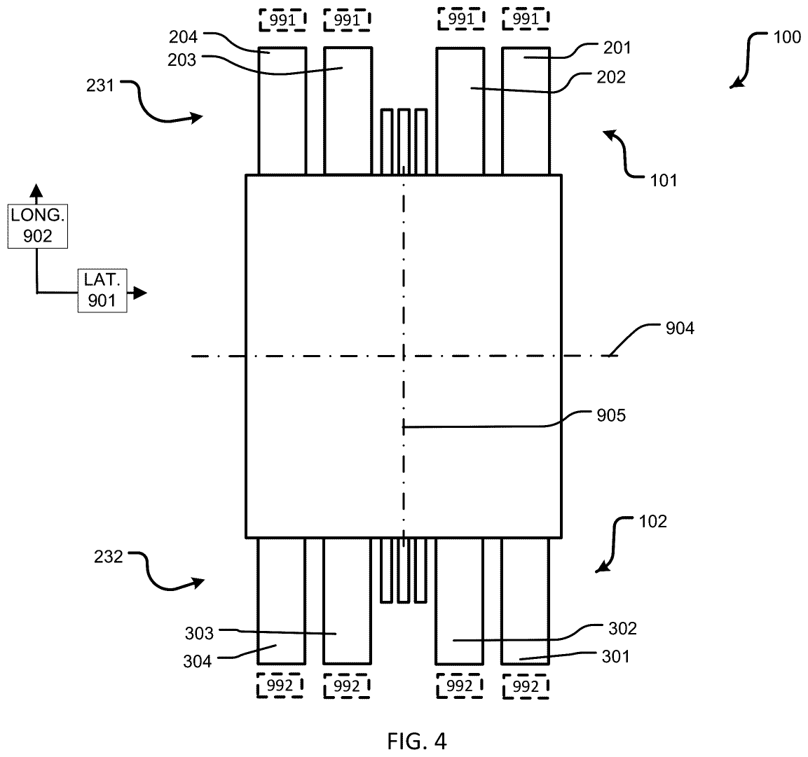

FIG. 4 illustrates a top view of an exemplary implementation power module according to aspects of the disclosure.

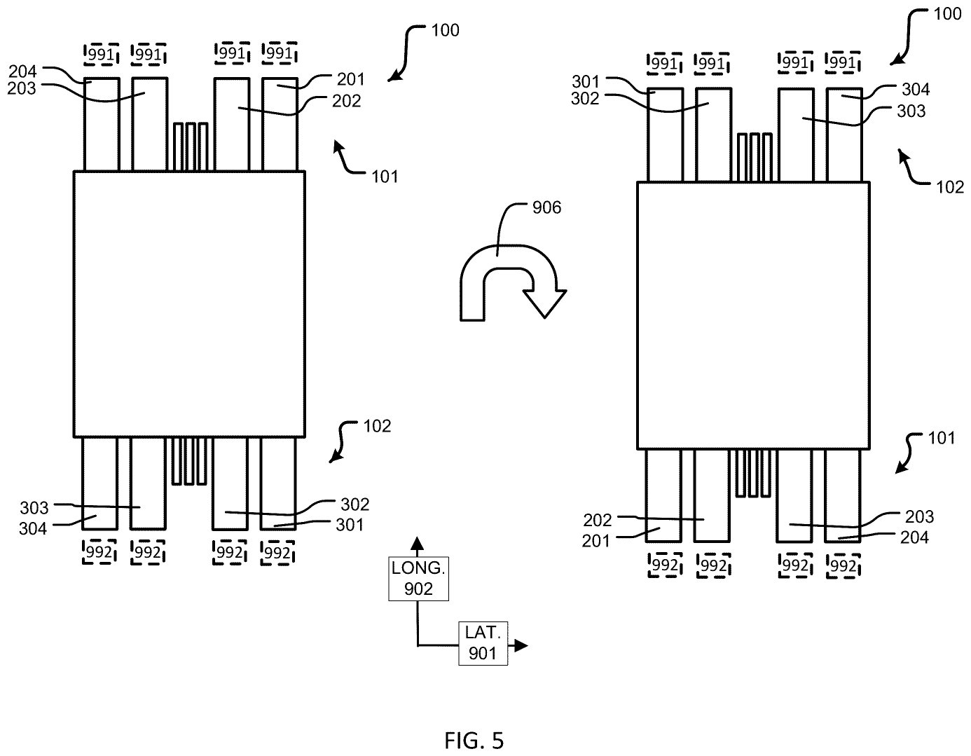

FIG. 5 illustrates top views of the power module of FIG. 4 prior to reversal and after reversal.

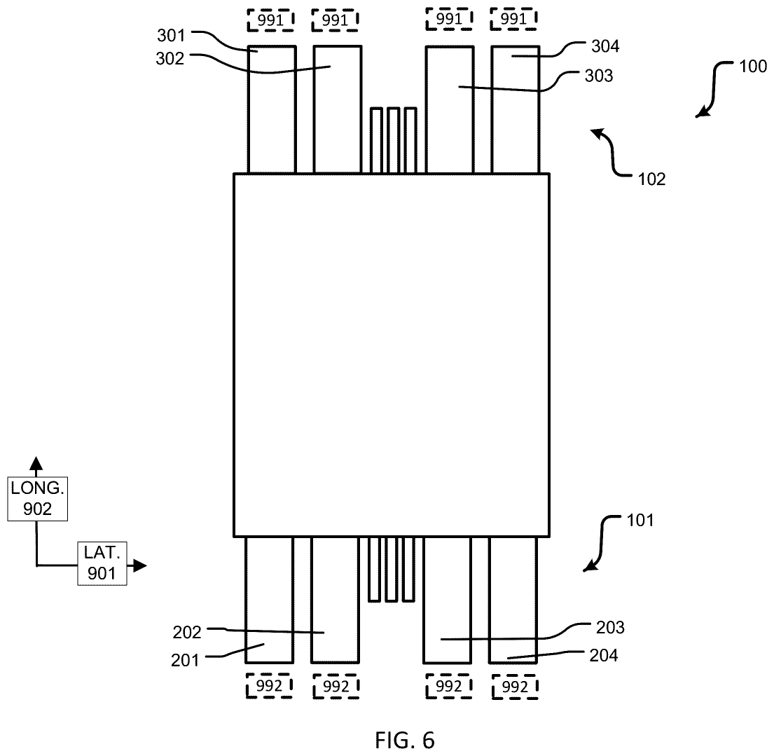

FIG. 6 illustrates a top view of the power module according to FIG. 4 after being reversed.

In aspects, the power module 100 may implement the first power terminals 231 as a first power terminal 201, a second power terminal 202, a third power terminal 203, and a fourth power terminal 204.

In aspects, the power module 100 may implement the second power terminals 232 as a first power terminal 301, a second power terminal 302, a third power terminal 303, and a fourth power terminal 304.

In particular, the first power terminal 201, the second power terminal 202, the third power terminal 203, and the fourth power terminal 204 may be arranged at a first power module side 101 of the power module 100; and the first power terminal 301, the second power terminal 302, the third power terminal 303, and the fourth power terminal 304 may be arranged at a second power module side 102 of the power module 100.

Further, the first power terminal 201, the second power terminal 202, the third power terminal 203, and the fourth power terminal 204 may connect to the respective first power connections 991 to an application (illustrated schematically); and the first power terminal 301, the second power terminal 302, the third power terminal 303, and the fourth power terminal 304 may connect to the respective second power connections 992 to the application (illustrated schematically).

In aspects as disclosed herein, the power module 100 may be configured as a reversible power module, a reversible power package, and/or the like such that the power module 100 may be repositioned or reoriented, such as by rotation about an axis perpendicular to the lateral axis 901 and a longitudinal axis 902. More specifically, a reversible power module, a reversible power package, and/or the like as disclosed herein may be an implementation of the power module 100 configured to allow a physical positioning and/or orientation of the power module 100 to be reversed or reoriented and provide commensurate operation of the power module 100.

In aspects, an arrangement and location of the first power terminal 201, the second power terminal 202, the third power terminal 203, and the fourth power terminal 204 may be symmetrical about the lateral axis of symmetry 904 with respect to an arrangement and location the first power terminal 301, the second power terminal 302, the third power terminal 303, and the fourth power terminal 304.

In aspects, an arrangement and location of the first power terminal 201 and the second power terminal 202 on the first power module side 101 may be symmetrical with respect to an arrangement and location the third power terminal 203, and the fourth power terminal 204 on the first power module side 101.

In aspects, an arrangement and location of the first power terminal 301 and the second power terminal 302 on the second power module side 102 may be symmetrical with respect to an arrangement and location the third power terminal 303, and the fourth power terminal 304 on the second power module side 102.

In aspects, an arrangement and location of the first power terminal 201, the second power terminal 202, the first power terminal 301 and the second power terminal 302 may be symmetrical about the longitudinal axis of symmetry 905 with respect to an arrangement and location the fourth power terminal 204, the third power terminal 203, the fourth power terminal 304, and the third power terminal 303.

As illustrated in FIG. 5, a positioning of the power module 100 is illustrated with an initial orientation on a left side of FIG. 5 consistent with FIG. 4. Thereafter, the power module 100 may be reversed or reoriented as illustrated on a right side of FIG. 5. In particular, arrow 906 illustrates an exemplary movement of the power module 100 illustrated on the left side of FIG. 5 to right side of FIG. 5, which results in a reorientation of the power module 100.

In particular, after reorienting the power module 100, locations of the first power terminal 201 and the fourth power terminal 304 may be reversed; locations of the second power terminal 202 and the third power terminal 303 are reversed, locations of the locations of the third power terminal 203 and the second power terminal 302 may be reversed, and locations of the fourth power terminal 204 and the first power terminal 301 may be reversed. In particular, the first power terminal 201, the second power terminal 202, the third power terminal 203, and the fourth power terminal 204 may now connect to the respective second power connections 992; and the fourth power terminal 304, the third power terminal 303, the second power terminal 302, and the first power terminal 301 may now connect to the respective first power connections 991.

In this regard, the power module 100 may be configured to operate in a manner when the first power terminal 201, the second power terminal 202, the third power terminal 203, and the fourth power terminal 204 connect to the respective first power connections 991 and the fourth power terminal 304, the third power terminal 303, the second power terminal 302, and the first power terminal 301 connect to the respective second power connections 992 of the application components as illustrated in FIG. 4.

Further, the power module 100 may be configured to operate in a same manner when the first power terminal 201, the second power terminal 202, the third power terminal 203, and the fourth power terminal 204 connect to the respective second power connections 992 and the fourth power terminal 304, the third power terminal 303, the second power terminal 302, and the first power terminal 301 connect to the respective first power connections 991 as illustrated in FIG. 6.

It should be noted that the power module 100 is illustrated implementing four power terminals on the first power module side 101 of the power module 100 and four power terminals on the second power module side 102 of the power module 100. However, in other aspects of the power module 100, there may be two, three, four, five, six, seven, or eight implementations of the first power terminals 231 on the first power module side 101 of the power module 100 and two, three, four, five, six, seven, or eight implementations of the second power terminals 232 on the second power module side 102 of the power module 100.

Aspects of the power module 100 illustrated in FIG. 4, FIG. 5, and FIG. 6 may optionally include any other features of the power module 100 as described and illustrated herein. Further, aspects of the power module 100 illustrated in FIG. 4, FIG. 5, and FIG. 6 and described therewith may optionally be implemented in any other implementations of the power module 100 as described and illustrated herein.

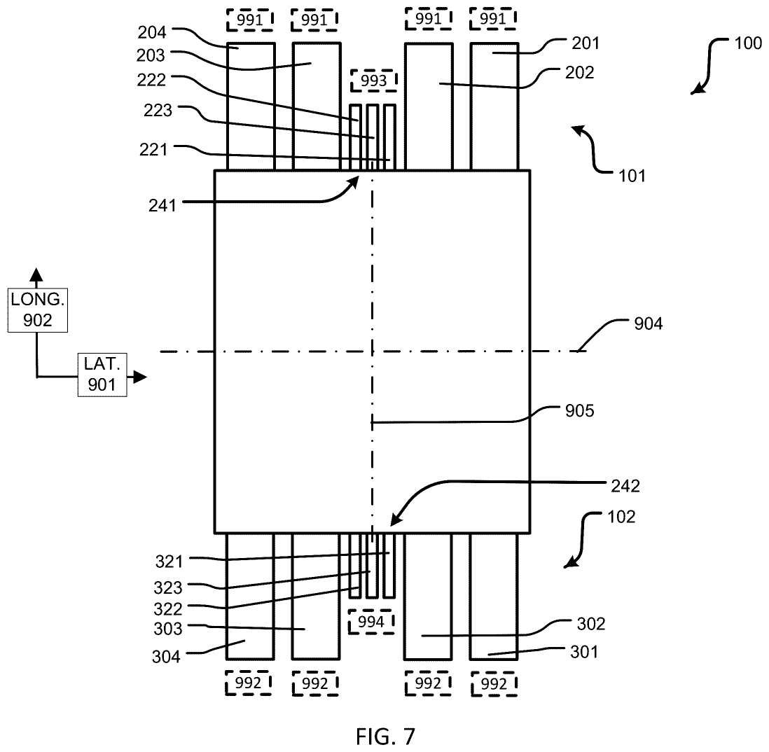

FIG. 7 illustrates a top view of a power module according to aspects of the disclosure.

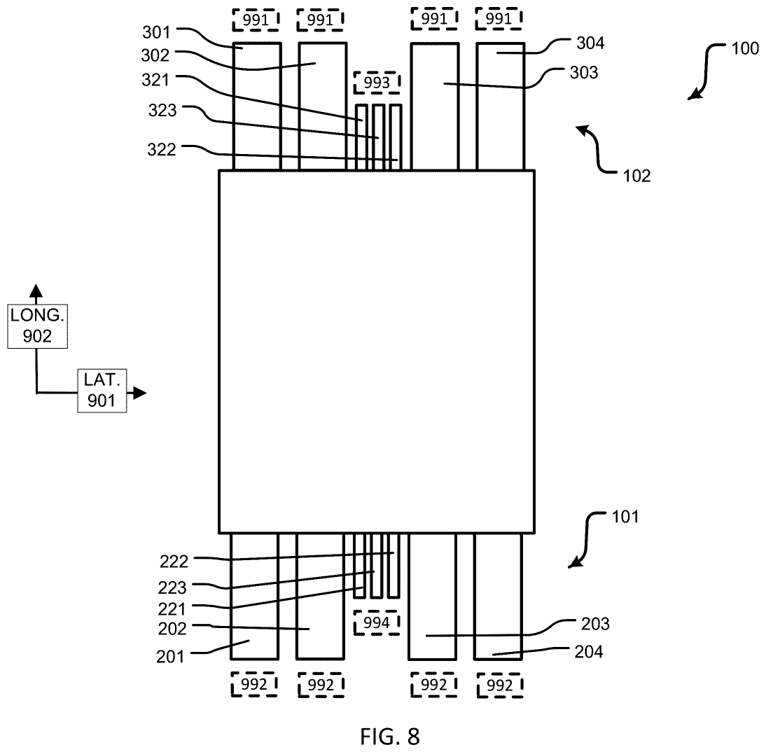

FIG. 8 illustrates a top view of the power module according to FIG. 7 after being reversed.

Aspects of the power module 100 illustrated in FIG. 7 and FIG. 8 may optionally include any other features of the power module 100 as described and illustrated herein. Further, aspects of the power module 100 illustrated in FIG. 7 and FIG. 8 and described therewith may optionally be implemented in any other implementations of the power module 100 as described and illustrated herein.

In aspects, the power module 100 may implement the first signal terminals 241 as a first signal terminal 221, a second signal terminal 222, and a third signal terminal 223.

In aspects, the power module 100 may implement the second signal terminals 242 as a first signal terminal 321, a second signal terminal 322, and a third signal terminal 323.

In particular, the first signal terminal 221, the second signal terminal 222, and the third signal terminal 223 may be arranged at the first power module side 101 of the power module 100; and the first signal terminal 321, the second signal terminal 322, and the third signal terminal 323 may be arranged at the second power module side 102 of the power module 100. Further, the first signal terminal 221, the second signal terminal 222, and the third signal terminal 223 may connect to respective first signal connections 993 of the application (illustrated schematically); and the first signal terminal 321, the second signal terminal 322, and the third signal terminal 323 may connect to respective second signal connections 994 of the application components (illustrated schematically).

In aspects, an arrangement and location of the first signal terminal 221, the second signal terminal 222, and the third signal terminal 223 on the first power module side 101 may be symmetrical with respect to an arrangement and location the first signal terminal 321, the second signal terminal 322, and the third signal terminal 323 on the second power module side 102.

In aspects, an arrangement and location of the first signal terminal 221, the second signal terminal 222, and the third signal terminal 223 may be symmetrical about the lateral axis of symmetry 904 with respect to an arrangement and location the first signal terminal 321, the second signal terminal 322, and the third signal terminal 323.

In aspects, an arrangement and location of the first power terminals 231 on the first power module side 101 may be symmetrical with respect to an arrangement and location the second power terminals 232 on the second power module side 102.

In aspects, an arrangement and location of the first signal terminal 221, the second signal terminal 222, and the third signal terminal 223 on the first power module side 101 may be symmetrical with respect to one side of the first power module side 101 and another side of the first power module side 101. In aspects, an arrangement and location the first signal terminal 321, the second signal terminal 322, and the third signal terminal 323 on the second power module side 102 may be symmetrical with respect to one side of the second power module side 102 and another side of the second power module side 102.

In aspects, an arrangement and location of the second signal terminal 222 and the third signal terminal 223 may be symmetrical about the longitudinal axis of symmetry 905. In aspects, an arrangement and location of the second signal terminal 322 and the third signal terminal 323 may be symmetrical about the longitudinal axis of symmetry 905.

As illustrated in FIG. 7, a positioning of the power module 100 is illustrated with an initial orientation consistent with FIG. 4. Thereafter, the power module 100 may be reversed or reoriented as illustrated in FIG. 8, which is consistent with FIG. 6.

In particular, after reorienting the power module 100, locations of the second signal terminal 222 and the first signal terminal 321 may be reversed, locations of the first signal terminal 221 and the second signal terminal 322 may be reversed, and locations of the third signal terminal 223 and the third signal terminal 323 may be reversed. In particular, the first signal terminal 321, the second signal terminal 322, and the third signal terminal 323 may now connect to the respective first signal connections 993; and the second signal terminal 222, the first signal terminal 221, and the third signal terminal 223 may now connect to the respective second signal connections 994.

In this regard, the power module 100 may be configured to operate in a manner when the first signal terminal 321, the second signal terminal 322, and the third signal terminal 323 connect to the respective second signal connections 994; and the second signal terminal 222, the first signal terminal 221, and the third signal terminal 223 connect to the respective first signal connections 993 as illustrated in FIG. 7.

Further, the power module 100 may be configured to operate in a same manner when the first signal terminal 321, the second signal terminal 322, and the third signal terminal 323 connect to the respective first signal connections 993; and the second signal terminal 222, the first signal terminal 221, and the third signal terminal 223 connect to the respective second signal connections 994 as illustrated in FIG. 8. In aspects, one of the first signal terminals 241 and/or one of the second signal terminals 242 may be arranged on the longitudinal axis of symmetry 905. For example, the third signal terminal 223 and the third signal terminal 323 are arranged on the longitudinal axis of symmetry 905.

It should be noted that the power module 100 is illustrated implementing three signal terminals on the first power module side 101 of the power module 100 and three signal terminals on the second power module side 102 of the power module 100. However, in other aspects of the power module 100, there may be two, three, four, five, six, seven, or eight implementations of the first signal terminals 241 on the first power module side 101 of the power module 100 and two, three, four, five, six, seven, or eight implementations of the second signal terminals 242 on the second power module side 102 of the power module 100.

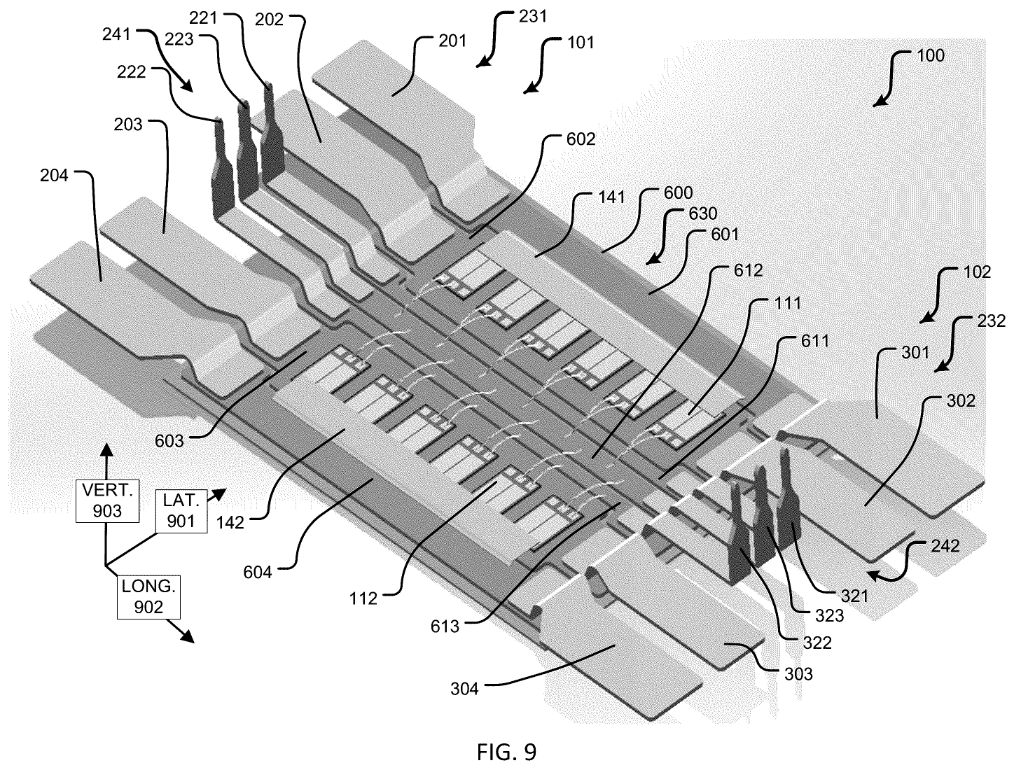

FIG. 9 illustrates a partial perspective view of an exemplary implementation a power module according to aspects of the disclosure.

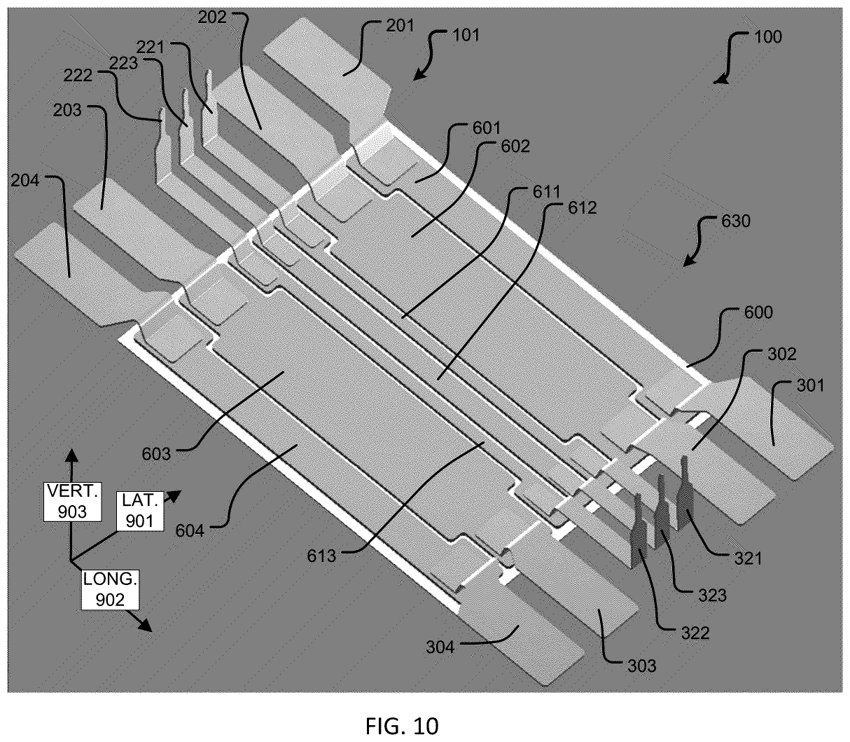

FIG. 10 illustrates a further partial perspective view of the exemplary implementation the power module according to FIG. 9.

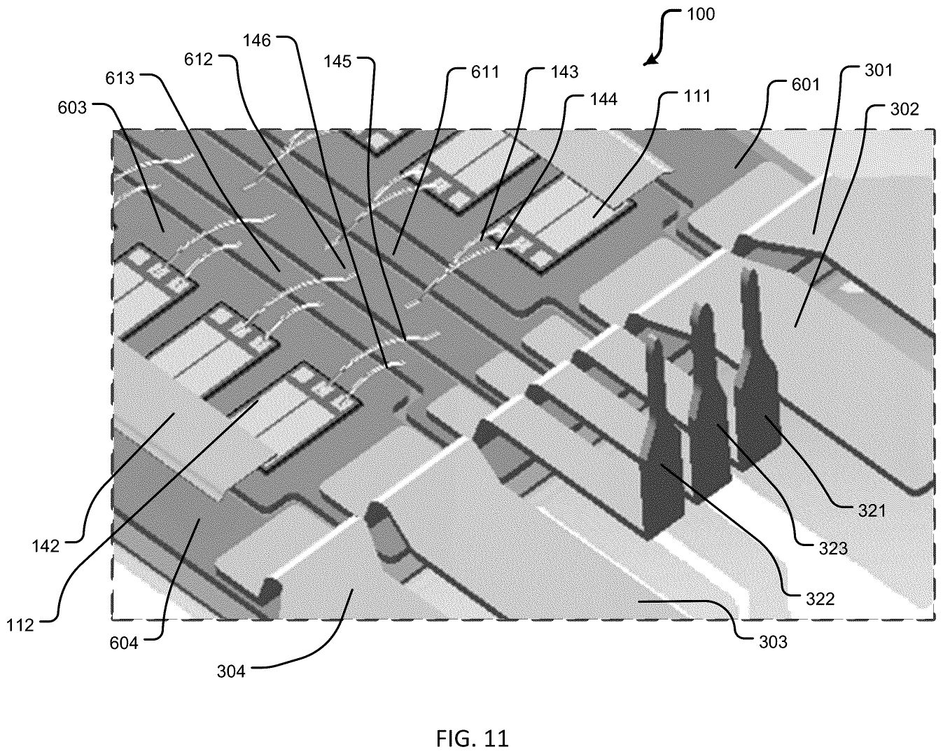

FIG. 11 illustrates a further partial perspective view of the exemplary implementation the power module according to FIG. 9.

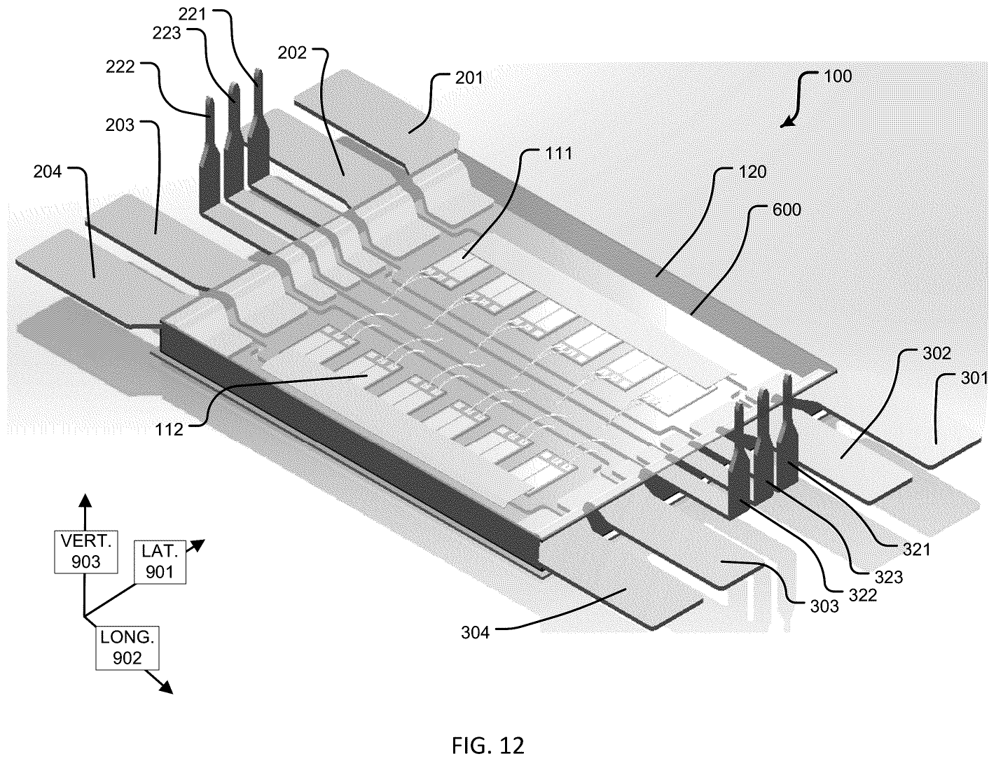

FIG. 12 illustrates a perspective view of the exemplary implementation the power module according to FIG. 9.

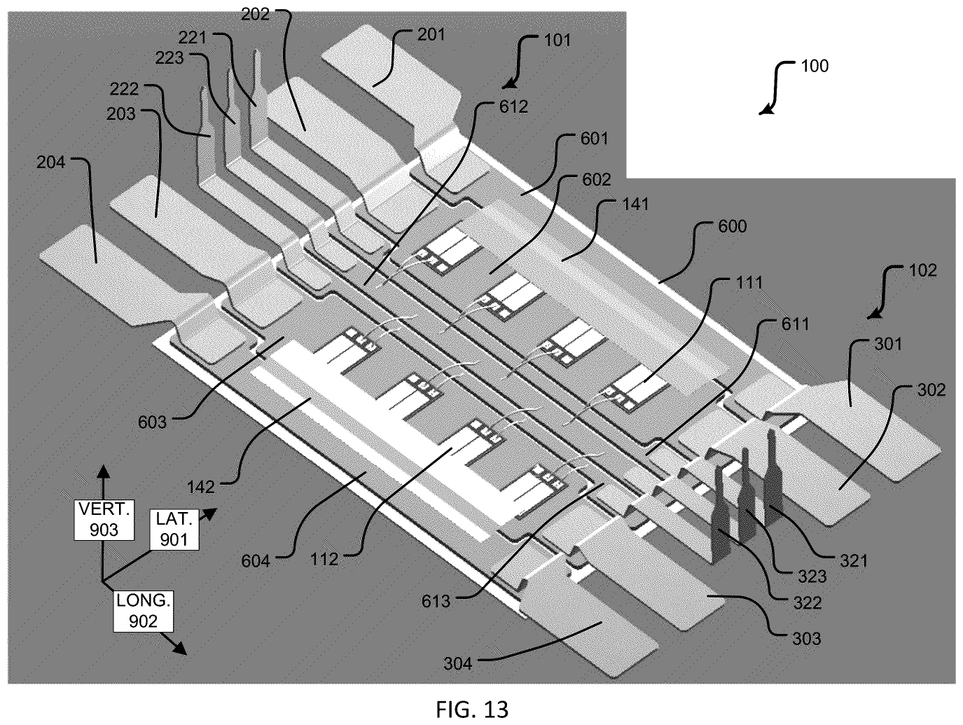

FIG. 13 illustrates another partial perspective view of the exemplary implementation the power module according to FIG. 9.

Aspects of the power module 100 illustrated in FIG. 9, FIG. 10, FIG. 11, FIG. 12, and FIG. 13 may optionally include any other features of the power module 100 as described and illustrated herein. Further, aspects of the power module 100 illustrated in FIG. 9, FIG. 10, FIG. 11, FIG. 12, and FIG. 13 and described therewith may optionally be implemented in any other implementations of the power module 100 as described and illustrated herein.

Further, the power module 100 may implement the plurality of power devices 130 with at least one first power device 111, at least one second power device 112, and/or the like.

In aspects, the power substrate 600 may include the at least one power trace 620. In aspects, the at least one power trace 620 may implement a first power trace 601. The first power trace 601 may extend at least partially from the first power module side 101 to the second power module side 102 along the longitudinal axis 902. In aspects, the first power trace 601 may be a power device source trace.

In aspects, the first power terminal 201 may be connected to the first power trace 601 at the first power module side 101; and the first power terminal 301 may be connected to the first power trace 601 at the second power module side 102. In aspects, the first power terminal 201, the first power trace 601, and the first power terminal 301 may be all electrically connected. In aspects, the first power terminal 301 may be connected to the first power trace 601 by an adhesive, soldering, sintering, eutectic bonding, thermal compression bonding, ultrasonic bonding/welding, and/or the like as described herein. In aspects, the first power terminal 201 may be connected to the first power trace 601 with by an adhesive, soldering, sintering, eutectic bonding, thermal compression bonding, ultrasonic bonding/welding, and/or the like as described herein. Accordingly, the construction and implementation with the first power terminal 201, the first power trace 601, and the first power terminal 301 electrically connected may allow implementation of the power module 100 to be reversible.

In aspects, the at least one power trace 620 may include a second power trace 602. The second power trace 602 may extend at least partially from the first power module side 101 to the second power module side 102 along the longitudinal axis 902. In aspects, the second power trace 602 may be a power device drain trace.

In aspects, the second power terminal 202 may be connected to the second power trace 602 at the first power module side 101. In aspects, the second power terminal 202 may be connected to the second power trace 602 by an adhesive, soldering, sintering, eutectic bonding, thermal compression bonding, ultrasonic bonding/welding, and/or the like as described herein.

In aspects, the second power terminal 302 may be connected to the second power trace 602 at the second power module side 102. In aspects, the second power terminal 302 may be connected to the second power trace 602 by an adhesive, soldering, sintering, eutectic bonding, thermal compression bonding, ultrasonic bonding/welding, and/or the like as described herein.

In aspects, the second power terminal 202, the second power trace 602, and the second power terminal 302 are all electrically connected. Accordingly, the construction and implementation with the second power terminal 202, the second power trace 602, and the second power terminal 302 electrically connected may allow implementation of the power module 100 to be reversible.

In aspects, the at least one power trace 620 may include a third power trace 603. The third power trace 603 may extend at least partially from the first power module side 101 to the second power module side 102 along the longitudinal axis 902. In aspects, the third power trace 603 may be a power device drain trace.

In aspects, the third power terminal 203 may be connected to the third power trace 603 at the first power module side 101. In aspects, the third power terminal 203 may be connected to the third power trace 603 by an adhesive, soldering, sintering, eutectic bonding, thermal compression bonding, ultrasonic bonding/welding, and/or the like as described herein.

In aspects, the third power terminal 303 may be connected to the third power trace 603 at the second power module side 102. In aspects, the third power terminal 303 may be connected to the third power trace 603 by an adhesive, soldering, sintering, eutectic bonding, thermal compression bonding, ultrasonic bonding/welding, and/or the like as described herein. In aspects, the third power terminal 203, the third power trace 603, and the third power terminal 303 are all electrically connected. Accordingly, the construction and implementation with the third power terminal 203, the third power trace 603, and the third power terminal 303 electrically connected may allow implementation of the power module 100 to be reversible.

In aspects, the at least one power trace 620 may include a fourth power trace 604. The fourth power trace 604 may extend at least partially from the first power module side 101 to the second power module side 102 along the longitudinal axis 902. In aspects, the fourth power trace 604 may be a power device source trace.

In aspects, the fourth power terminal 204 may be connected to the fourth power trace 604 at the first power module side 101. In aspects, the fourth power terminal 204 may be connected to the fourth power trace 604 by an adhesive, soldering, sintering, eutectic bonding, thermal compression bonding, ultrasonic bonding/welding, and/or the like as described herein.

In aspects, the fourth power terminal 304 may be connected to the fourth power trace 604 at the second power module side 102. In aspects, the fourth power terminal 304 may be connected to the fourth power trace 604 by an adhesive, soldering, sintering, eutectic bonding, thermal compression bonding, ultrasonic bonding/welding, and/or the like as described herein.

In aspects, the fourth power terminal 204, the fourth power trace 604, and the fourth power terminal 304 are all electrically connected. Accordingly, the construction and implementation with the fourth power terminal 204, the fourth power trace 604, and the fourth power terminal 304 electrically connected may allow implementation of the power module 100 to be reversible.

Additionally, the at least one first power device 111 may be arranged on and attached to the second power trace 602. In aspects, a source or emitter of the at least one first power device 111 may be electrically attached to the first power trace 601. In aspects, the at least one first power device 111 may be electrically attached to the second power trace 602 by an adhesive, soldering, sintering, eutectic bonding, thermal compression bonding, ultrasonic bonding/welding, and/or the like as described herein.

Additionally, the at least one second power device 112 may be arranged on and attached to the third power trace 603. In aspects, a source or emitter of the at least one second power device 112 may be electrically attached to the fourth power trace 604. In aspects, the at least one second power device 112 may be electrically attached to the third power trace 603 by an adhesive, soldering, sintering, eutectic bonding, thermal compression bonding, ultrasonic bonding/welding, and/or the like as described herein.

Further, the at least one first power device 111 may be electrically connected to the first power trace 601 with a first power interconnect 141. In aspects, the first power interconnect 141 may connect to a source or emitter of the at least one first power device 111. In aspects, the first power interconnect 141 may connect to the at least one first power device 111 by an adhesive, soldering, sintering, eutectic bonding, thermal compression bonding, ultrasonic bonding/welding, and/or the like as described herein.

In aspects, the first power interconnect 141 may be connected to the first power trace 601. In aspects, the first power interconnect 141 may be connected to the first power trace 601 by an adhesive, soldering, sintering, eutectic bonding, thermal compression bonding, ultrasonic bonding/welding, and/or the like as described herein. The first power interconnect 141 may be implemented as one or more wire bonds, ribbons, clips, and/or the like. As illustrated in FIG. 9, the first power interconnect 141 is implemented as a clip.

Further, the at least one second power device 112 may be electrically connected to the fourth power trace 604 with a second power interconnect 142. In aspects, the second power interconnect 142 may connect to a source or emitter of the at least one second power device 112. In aspects, the second power interconnect 142 may connect to the at least one second power device 112 by an adhesive, soldering, sintering, eutectic bonding, thermal compression bonding, ultrasonic bonding/welding, and/or the like as described herein.

In aspects, the second power interconnect 142 may be connected to the fourth power trace 604. In aspects, the second power interconnect 142 may be connected to the fourth power trace 604 by an adhesive, soldering, sintering, eutectic bonding, thermal compression bonding, ultrasonic bonding/welding, and/or the like as described herein. The second power interconnect 142 may be implemented as one or more wire bonds, ribbons, clips, and/or the like. As illustrated in FIG. 9, the second power interconnect 142 is implemented as a clip.

In aspects, the at least one signal trace 630 may include a first signal trace 611. In aspects, the first signal terminal 221 may be connected to the first signal trace 611 at the first power module side 101. In aspects, the first signal terminal 221 may be connected to the first signal trace 611 by an adhesive, soldering, sintering, eutectic bonding, thermal compression bonding, ultrasonic bonding/welding, and/or the like as described herein.

In aspects, the first signal terminal 321 may be connected to the first signal trace 611 at the second power module side 102. In aspects, the first signal terminal 321 may be connected to the first signal trace 611 by an adhesive, soldering, sintering, eutectic bonding, thermal compression bonding, ultrasonic bonding/welding, and/or the like as described herein.

In aspects, the at least one first power device 111 may be connected to the first signal trace 611 with a first signal interconnect 143 as illustrated in FIG. 11. In aspects, the first signal trace 611 may be a source Kelvin trace. In aspects, the first signal interconnect 143 may connect to a source Kelvin of the at least one first power device 111. In aspects, the first signal interconnect 143 may connect to the at least one first power device 111 by an adhesive, soldering, sintering, eutectic bonding, thermal compression bonding, ultrasonic bonding/welding, and/or the like as described herein. The first signal interconnect 143 may be implemented as one or more wire bonds, ribbons, clips, and/or the like. As illustrated in FIG. 10, the first signal interconnect 143 is implemented as a wire bond.

In aspects, the at least one signal trace 630 may include a second signal trace 612. In aspects, the third signal terminal 223 may be connected to the second signal trace 612 at the first power module side 101. In aspects, the third signal terminal 223 may be connected to the second signal trace 612 by an adhesive, soldering, sintering, eutectic bonding, thermal compression bonding, ultrasonic bonding/welding, and/or the like as described herein.

In aspects, the third signal terminal 323 may be connected to the second signal trace 612 at the second power module side 102. In aspects, the third signal terminal 323 may be connected to the second signal trace 612 by an adhesive, soldering, sintering, eutectic bonding, thermal compression bonding, ultrasonic bonding/welding, and/or the like as described herein.

In aspects, the at least one first power device 111 may be connected to the second signal trace 612 with a signal interconnect 144. In aspects, the second signal trace 612 may be a gate trace. In aspects, the signal interconnect 144 may connect to a gate of the at least one first power device 111. In aspects, the signal interconnect 144 may connect to the at least one first power device 111 by an adhesive, soldering, sintering, eutectic bonding, thermal compression bonding, ultrasonic bonding/welding, and/or the like as described herein. The signal interconnect 144 may be implemented as one or more wire bonds, ribbons, clips, and/or the like. As illustrated in FIG. 10, the signal interconnect 144 is implemented as a wire bond.

In aspects, the at least one second power device 112 may be connected to the second signal trace 612 with a signal interconnect 145. In aspects, the signal interconnect 145 may connect to a gate of the at least one second power device 112. In aspects, the signal interconnect 145 may connect to the at least one second power device 112 by an adhesive, soldering, sintering, eutectic bonding, thermal compression bonding, ultrasonic bonding/welding, and/or the like as described herein. The signal interconnect 145 may be implemented as one or more wire bonds, ribbons, clips, and/or the like. As illustrated in FIG. 10, the signal interconnect 145 is implemented as a wire bond.

In aspects, the at least one signal trace 630 may include a third signal trace 613. In aspects, the second signal terminal 222 may be connected to the third signal trace 613 at the first power module side 101. In aspects, the second signal terminal 222 may be connected to the third signal trace 613 by an adhesive, soldering, sintering, eutectic bonding, thermal compression bonding, ultrasonic bonding/welding, and/or the like as described herein.

In aspects, the second signal terminal 322 may be connected to the third signal trace 613 at the second power module side 102. In aspects, the second signal terminal 322 may be connected to the third signal trace 613 by an adhesive, soldering, sintering, eutectic bonding, thermal compression bonding, ultrasonic bonding/welding, and/or the like as described herein.

In aspects, the at least one second power device 112 may be connected to the third signal trace 613 with a third power interconnect 146. In aspects, the third signal trace 613 may be a source Kelvin trace. In aspects, the third power interconnect 146 may connect to a source Kelvin of the at least one second power device 112. In aspects, the third power interconnect 146 may connect to the at least one second power device 112 by an adhesive, soldering, sintering, eutectic bonding, thermal compression bonding, ultrasonic bonding/welding, and/or the like as described herein. The third power interconnect 146 may be implemented as one or more wire bonds, ribbons, clips, and/or the like. As illustrated in FIG. 11, the third power interconnect 146 is implemented as a wire bond.

As illustrated in FIG. 12, the power module 100 may include an assembly 120. The assembly 120 may include a housing, one or more housing sidewalls, a molded portion, an over-molded portion, an encapsulation portion, a frame portion, a ceramic frame portion and/or the like. The assembly 120 may be formed of a synthetic material, encapsulated through over molding, ceramic frames with silica gel, epoxy-resin, and/or the like. In one aspect, the assembly 120 may be an injection molded plastic element. The assembly 120 may provide electrical insulation, voltage creepage and clearance, structural support, and/or the like.

In aspects, the power module 100 may implement fewer implementations of the at least one first power device 111 and the at least one second power device 112 as illustrated in FIG. 13. In this regard, there may be any number of the at least one first power device 111 and the at least one second power device 112 implemented by the power module 100.

Referring back to FIG. 10, in aspects, the first power terminal 201 and the fourth power terminal 204 may be arranged on the first power module side 101 on opposing lateral ends of the lateral axis 901 thereof; and the first power terminal 301 and the fourth power terminal 304 may be arranged on the second power module side 102 on opposing lateral ends of the lateral axis 901 thereof.

In aspects, the second power terminal 202 and the third power terminal 203 may be arranged between the first power terminal 201 and the fourth power terminal 204; and the second power terminal 302 and the third power terminal 303 may be arranged between the first power terminal 301 and the fourth power terminal 304.

In aspects, the first signal terminal 221, the second signal terminal 222, and the third signal terminal 223 may be arranged between the second power terminal 202 and the third power terminal 203; and the first signal terminal 321, the second signal terminal 322, and the third signal terminal 323 may be arranged between the second power terminal 302 and the third power terminal 303.

In aspects, the first power trace 601 and the fourth power trace 604 may be arranged on the power substrate 600 on opposing lateral ends of the lateral axis 901 thereof. In aspects, the second power trace 602 and the third power trace 603 may be arranged between the first power trace 601 and the fourth power trace 604. In aspects, the first signal trace 611, the second signal trace 612, and the third signal trace 613 may be arranged between the second power trace 602 and the third power trace 603.

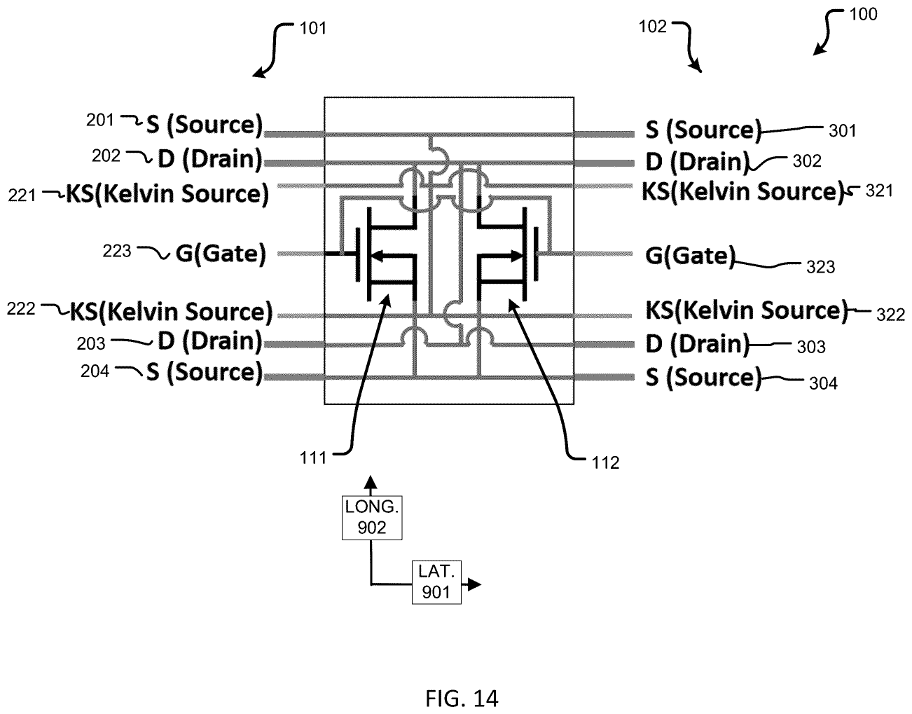

FIG. 14 illustrates is schematic of the power module 100 according to aspects of the disclosure.

In particular, FIG. 14 illustrates is schematic of the power module 100 and connections to the at least one first power device 111 and the at least one second power device 112. Moreover, FIG. 14 illustrates the connections of the at least one first power device 111 and the at least one second power device 112 to the first power terminal 201, the second power terminal 202, the third power terminal 203, the fourth power terminal 204, the first signal terminal 221, the second signal terminal 222, the third signal terminal 223, the first power terminal 301, the second power terminal 302, the third power terminal 303, the fourth power terminal 304, the first signal terminal 321, the third signal terminal 323, the second signal terminal 322, the third signal terminal 323, and/or the like.

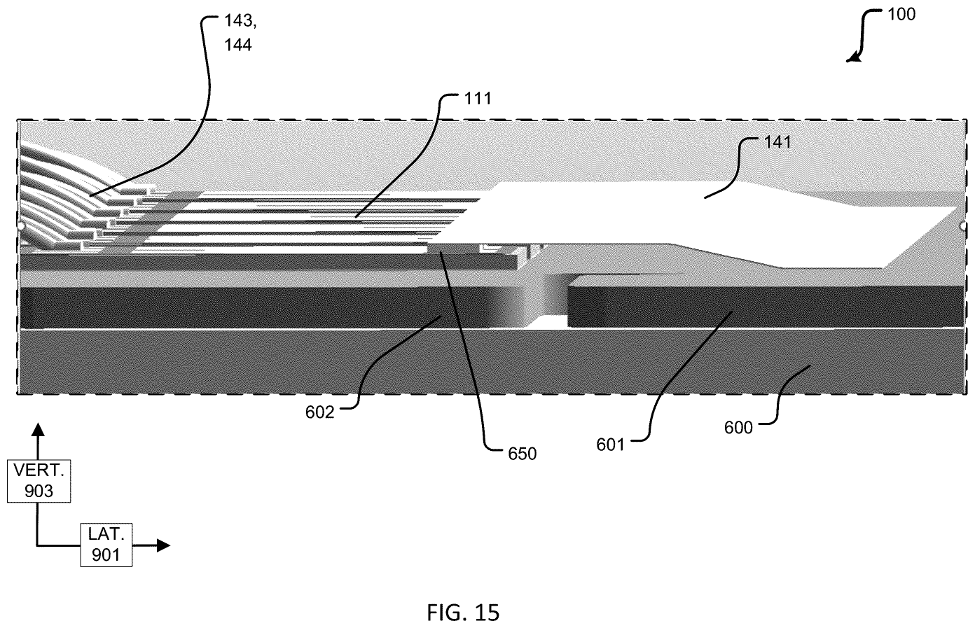

FIG. 15 illustrates a partial side view of the power module according to aspects of the disclosure.

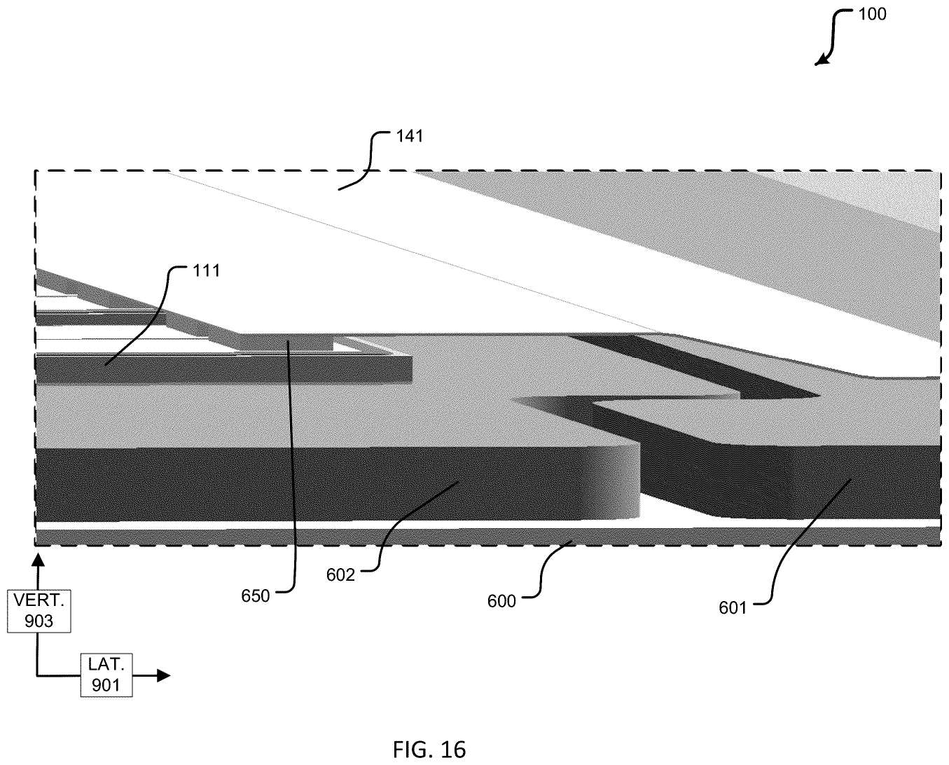

FIG. 16 illustrates a further partial side view of the power module according to FIG. 15.

Aspects of the power module 100 illustrated in FIG. 15 and FIG. 16 may optionally include any other features of the power module 100 as described and illustrated herein. Further, aspects of the power module 100 illustrated in FIG. 15 and FIG. 16 and described therewith may optionally be implemented in any other implementations of the power module 100 as described and illustrated herein.

In aspects, the power module 100 may be implemented with a riser 650 arranged between the first power interconnect 141 and the at least one first power device 111. Similarly, the riser 650 may be likewise arranged between the at least one second power device 112 and the second power interconnect 142 (not shown).

The riser 650 may be connected to the first power interconnect 141 by an adhesive, soldering, sintering, eutectic bonding, thermal compression bonding, ultrasonic bonding/welding, and/or the like as described herein. Further, the riser 650 may be connected to the at least one first power device 111 by an adhesive, soldering, sintering, eutectic bonding, thermal compression bonding, ultrasonic bonding/welding, and/or the like as described herein.

In aspects, the riser 650 may be connected to a top surface of the at least one first power device 111. In aspects, the riser 650 may extend along the vertical axis 903 from the top surface of the at least one first power device 111 to a lower surface of the first power interconnect 141.

In aspects, the riser 650 may be connected to a source connection of the at least one first power device 111. In aspects, the riser 650 may extend along the vertical axis 903 from the source connection of the at least one first power device 111 to a lower surface of the first power interconnect 141.

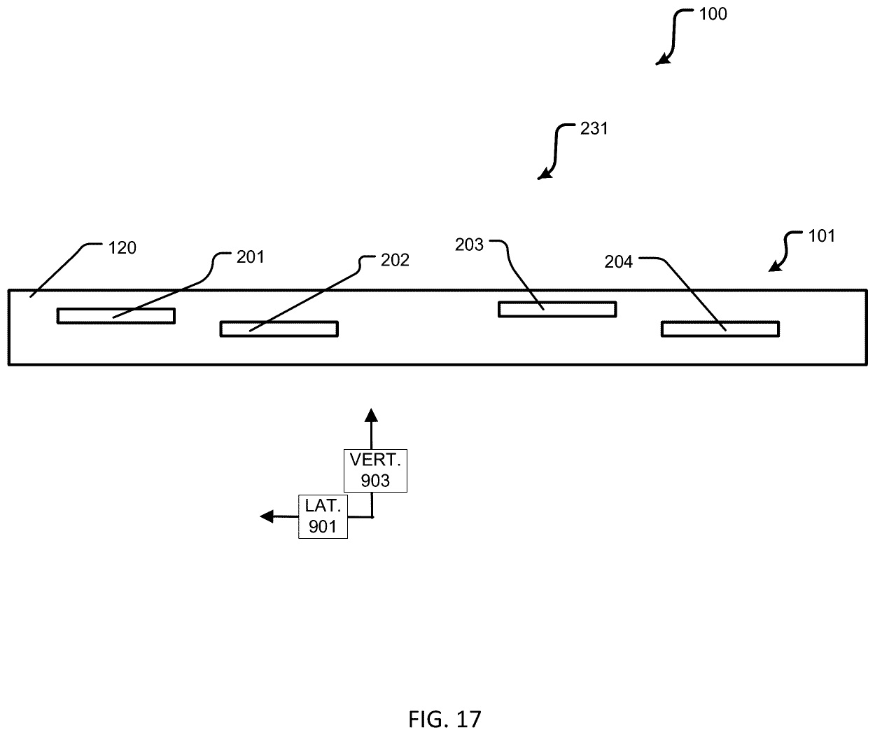

FIG. 17 illustrates an end view of the first power module side of the power module according to aspects of the disclosure.

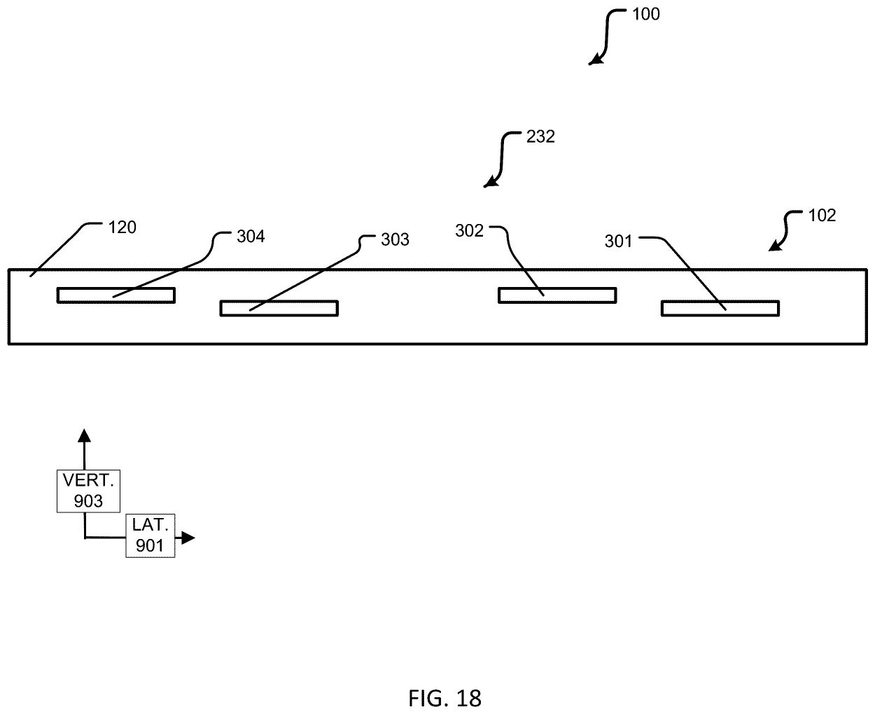

FIG. 18 illustrates an end view of the second power module side of the power module according to aspects of the disclosure.

Aspects of the power module 100 illustrated in FIG. 17 and FIG. 18 may optionally include any other features of the power module 100 as described and illustrated herein. Further, aspects of the power module 100 illustrated in FIG. 17 and FIG. 18 and described therewith may optionally be implemented in any other implementations of the power module 100 as described and illustrated herein.

As illustrated in FIG. 17, the first power terminals 231 may include power terminals implementations having connection portions that are at different vertical heights. In aspects, the first power terminals 231 may include power terminals implementations having connection portions that may be staggered vertically. In particular, the vertically staggered configurations of the first power terminals 231 may allow for easy paralleling of plural implementations of the power module 100.

In aspects, the first power terminal 201 may be vertically higher than the second power terminal 202; and the third power terminal 203 may be vertically higher than the fourth power terminal 204. However, other vertically staggered arrangements of the first power terminals 231 are contemplated as well.

As illustrated in FIG. 18, the second power terminals 232 may include power terminals implementations having connection portions that are at different vertical heights. In aspects, the second power terminals 232 may include power terminals implementations having connection portions that may be staggered vertically. In particular, the vertically staggered configurations of the second power terminals 232 may allow for easy paralleling of pleural implementations of the power module 100.

In aspects, the fourth power terminal 304 may be vertically higher than the third power terminal 303; and the second power terminal 302 may be vertically higher than the first power terminal 301. However, other vertically staggered arrangements of the first power terminals 231 are contemplated as well.

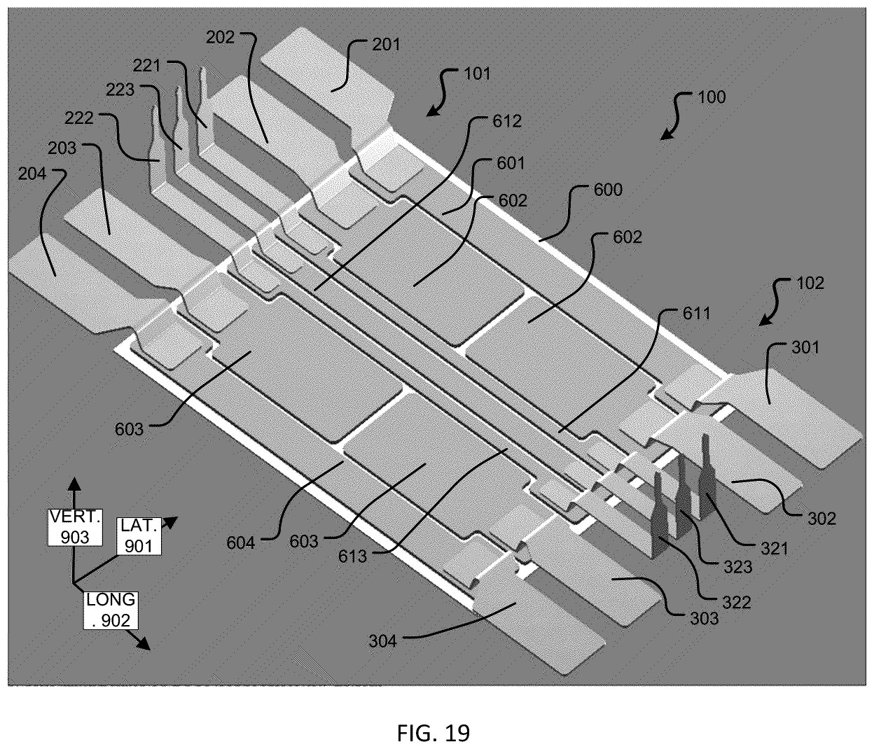

FIG. 19 illustrates a partial perspective view of an exemplary implementation a power module according to aspects of the disclosure.

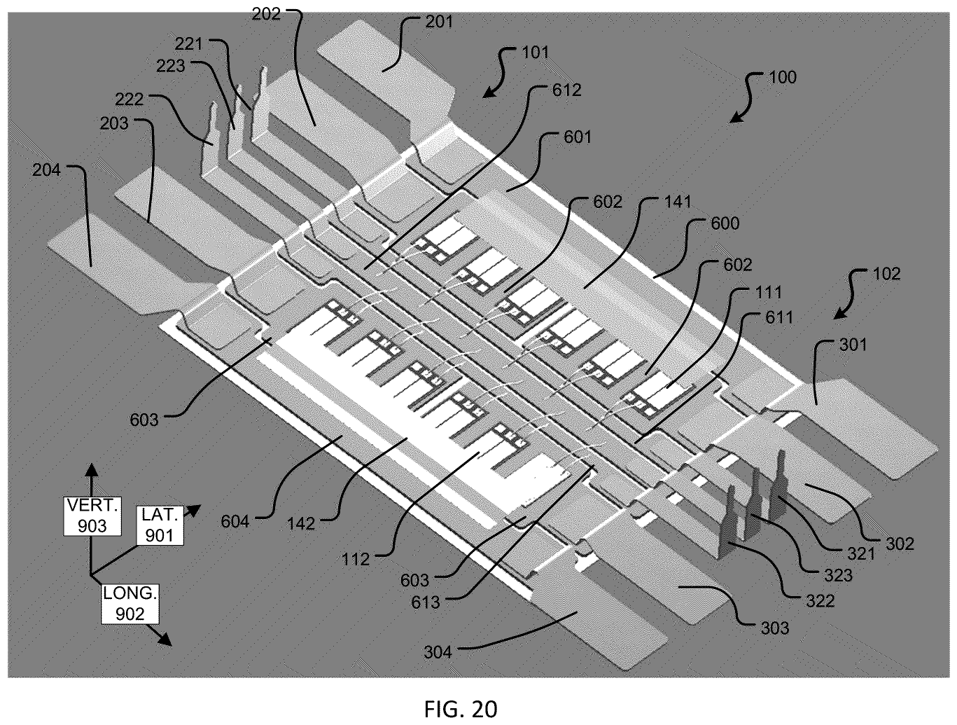

FIG. 20 illustrates a further partial perspective view of the exemplary implementation the power module according to FIG. 19.

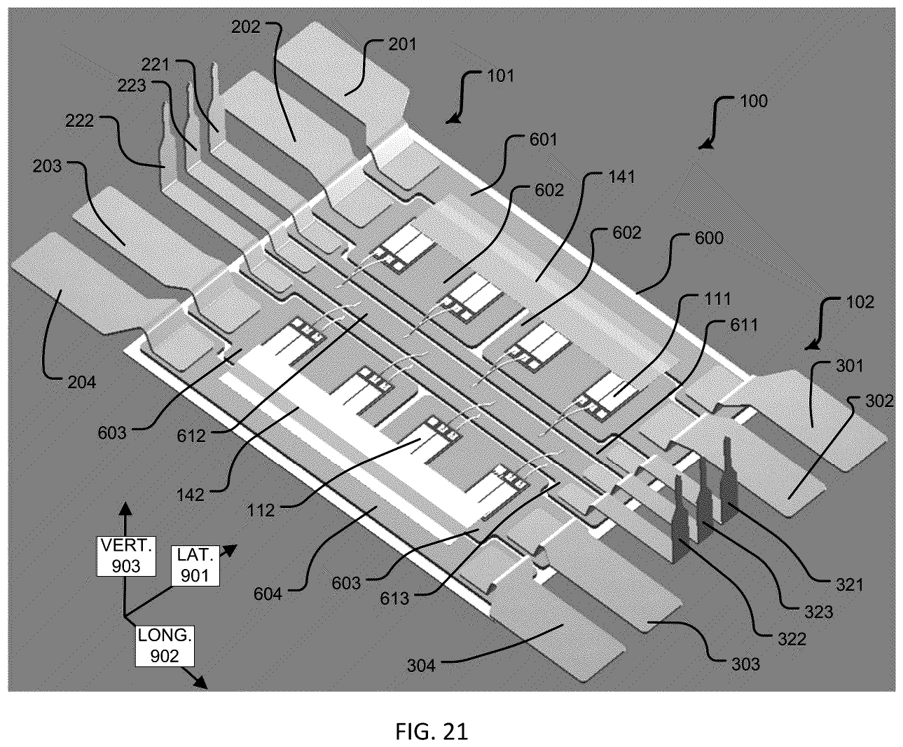

FIG. 21 illustrates a further partial perspective view of the exemplary implementation the power module according to FIG. 19.

Aspects of the power module 100 illustrated in FIG. 19, FIG. 20, and FIG. 21 may optionally include any other features of the power module 100 as described and illustrated herein. Further, aspects of the power module 100 illustrated in FIG. 19, FIG. 20, and FIG. 21 and described therewith may optionally be implemented in any other implementations of the power module 100 as described and illustrated herein.

As illustrated in FIG. 19, FIG. 20, and FIG. 21, the power module 100 may implement the second power trace 602 to have separate portions arranged on the power substrate 600. In aspects, the power module 100 may implement two separate portions of the second power trace 602. One portion of the second power trace 602 may connect to the second power terminal 202. Another portion of the second power trace 602 may connect to the second power terminal 302.

As illustrated in FIG. 19, FIG. 20, and FIG. 21, the power module 100 may implement the third power trace 603 to have separate portions arranged on the power substrate 600. In aspects, the power module 100 may implement two separate portions of the third power trace 603. One portion of the third power trace 603 may connect to the fourth power terminal 204. Another portion of the third power trace 603 may connect to the fourth power terminal 304.

FIG. 20 illustrates further details of the power module 100 as previously described herein. FIG. 21 illustrates implementations of the power module 100 having fewer implementations of the at least one first power device 111 and the at least one second power device 112. In this regard, there may be any number of the at least one first power device 111 and the at least one second power device 112 implemented by the power module 100.

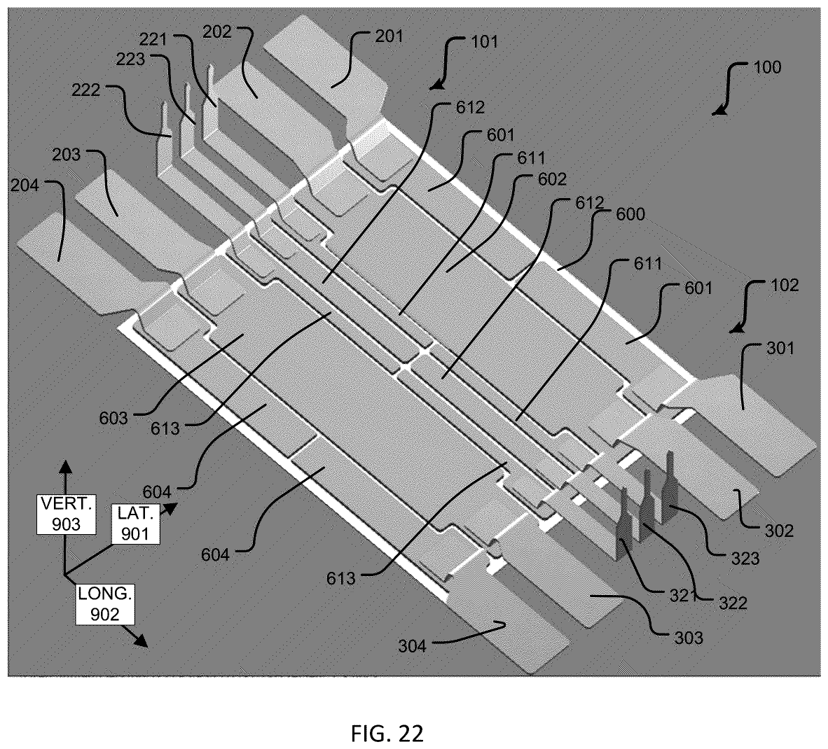

FIG. 22 illustrates a partial perspective view of an exemplary implementation a power module according to aspects of the disclosure.

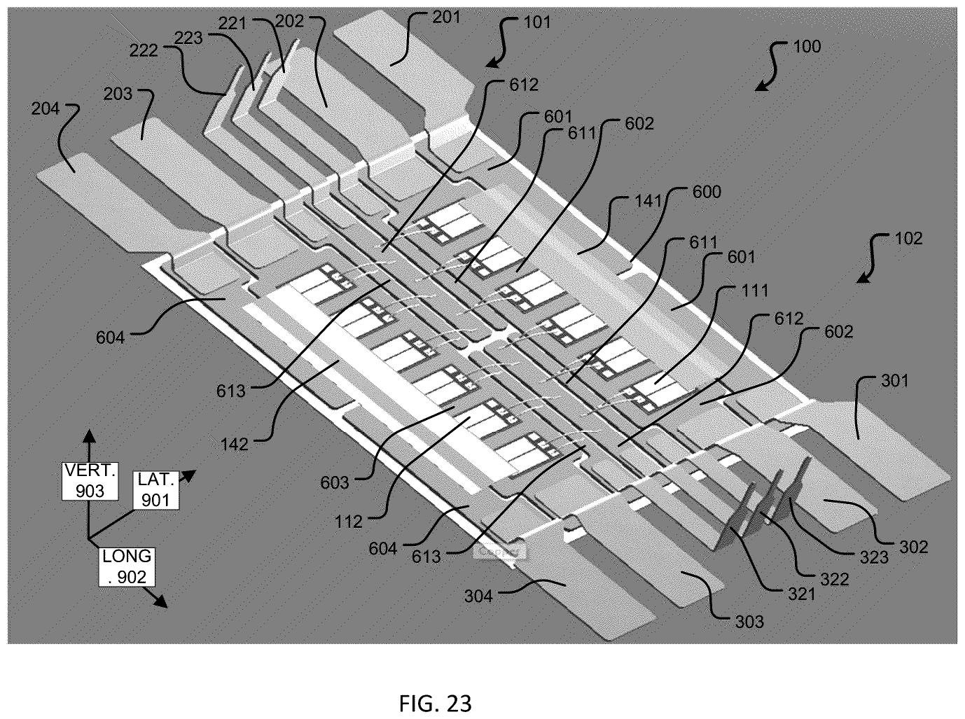

FIG. 23 illustrates a further partial perspective view of the exemplary implementation the power module according to FIG. 22.

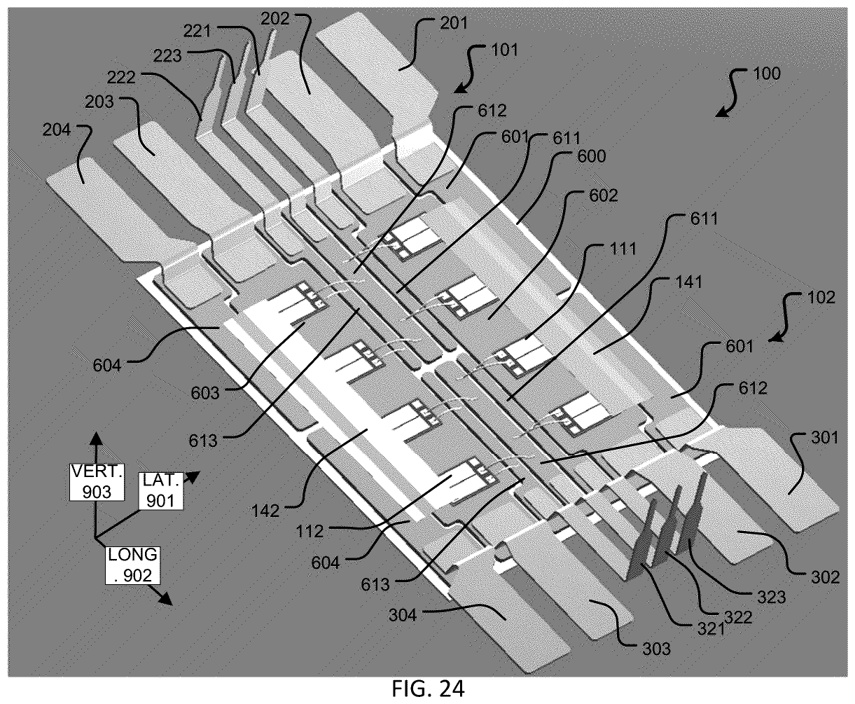

FIG. 24 illustrates a further partial perspective view of the exemplary implementation the power module according to FIG. 22.

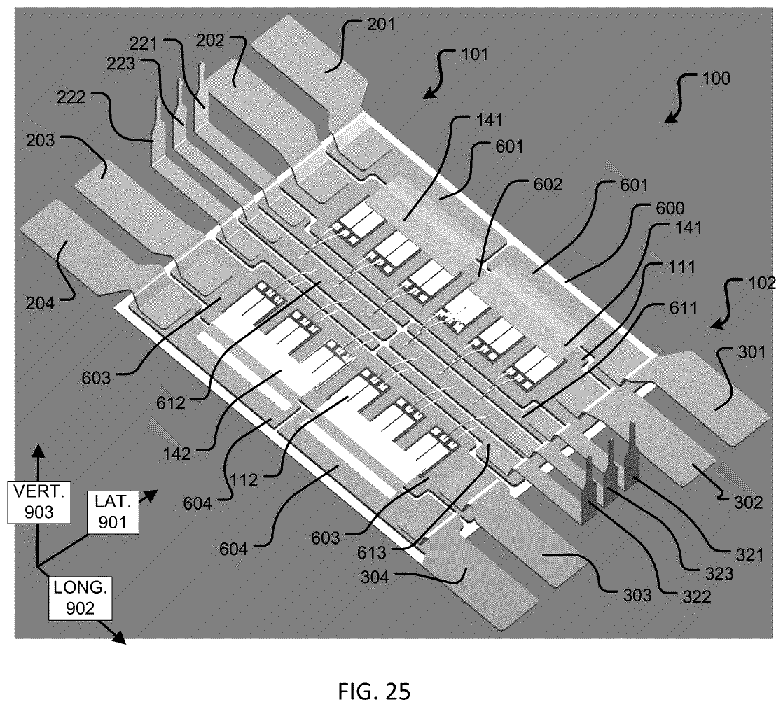

FIG. 25 illustrates a further partial perspective view of the exemplary implementation the power module according to FIG. 22.

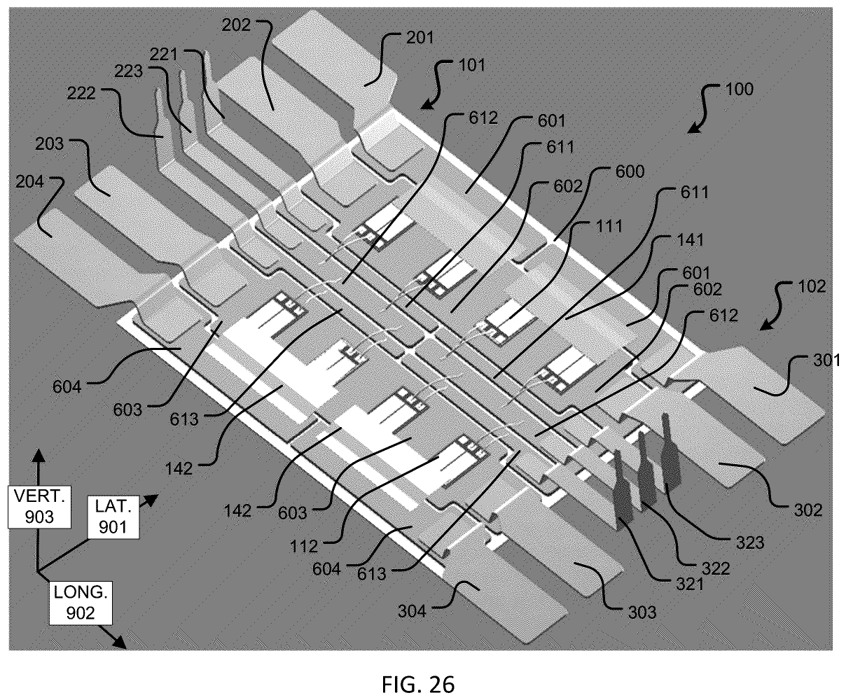

FIG. 26 illustrates a further partial perspective view of the exemplary implementation the power module according to FIG. 22.

Aspects of the power module 100 illustrated in FIG. 22, FIG. 23, FIG. 24, FIG. 25, and FIG. 26 may optionally include any other features of the power module 100 as described and illustrated herein. Further, aspects of the power module 100 illustrated in FIG. 22, FIG. 23, FIG. 24, FIG. 25, and FIG. 26 and described therewith may optionally be implemented in any other implementations of the power module 100 as described and illustrated herein.

As illustrated in FIG. 22, FIG. 23, FIG. 24, FIG. 25, and FIG. 26, the power module 100 may implement the first power trace 601 to have separate portions arranged on the power substrate 600. In aspects, the power module 100 may implement two separate portions of the first power trace 601. One portion of the first power trace 601 may connect to the first power terminal 201. Another portion of the first power trace 601 may connect to the first power terminal 301.

As further illustrated in FIG. 22, FIG. 23, FIG. 24, FIG. 25, and FIG. 26, the power module 100 may implement the fourth power trace 604 to have separate portions arranged on the power substrate 600. In aspects, the power module 100 may implement two separate portions of the fourth power trace 604. One portion of the fourth power trace 604 may connect to the fourth power terminal 204. Another portion of the fourth power trace 604 may connect to the fourth power terminal 304.

As illustrated in FIG. 22, FIG. 23, FIG. 24, FIG. 25, and FIG. 26, the power module 100 may implement the first signal trace 611 to have separate portions arranged on the power substrate 600. In aspects, the power module 100 may implement two separate portions of the first signal trace 611. One portion of the first signal trace 611 may connect to the first signal terminal 221. Another portion of the first signal trace 611 may connect to the first signal terminal 321.

As illustrated in FIG. 22, FIG. 23, FIG. 24, FIG. 25, and FIG. 26, the power module 100 may implement the second signal trace 612 to have separate portions arranged on the power substrate 600. In aspects, the power module 100 may implement two separate portions of the second signal trace 612. One portion of the second signal trace 612 may connect to the third signal terminal 223. Another portion of the second signal trace 612 may connect to the third signal terminal 323.

As illustrated in FIG. 22, FIG. 23, FIG. 24, FIG. 25, and FIG. 26, the power module 100 may implement the third signal trace 613 to have separate portions arranged on the power substrate 600. In aspects, the power module 100 may implement two separate portions of the third signal trace 613. One portion of the second signal trace 612 may connect to the second signal terminal 222. Another portion of the third signal trace 613 may connect to the second signal terminal 322.

FIG. 23 illustrates further details of the power module 100 as previously described herein. FIG. 24 illustrates implementations of the power module 100 having fewer implementations of the at least one first power device 111 and the at least one second power device 112. In this regard, there may be any number of the at least one first power device 111 and the at least one second power device 112 implemented by the power module 100.

As further illustrated in FIG. 25 in FIG. 26, the power module 100 may have separate implementations of the first power interconnect 141 attached to the first power trace 601; and the power module 100 may have separate implementations of the second power interconnect 142 attached to the fourth power trace 604.

FIG. 25 illustrates further details of the power module 100 as previously described herein. FIG. 26 illustrates implementations of the power module 100 having fewer implementations of the at least one first power device 111 and the at least one second power device 112. In this regard, there may be any number of the at least one first power device 111 and the at least one second power device 112 implemented by the power module 100.

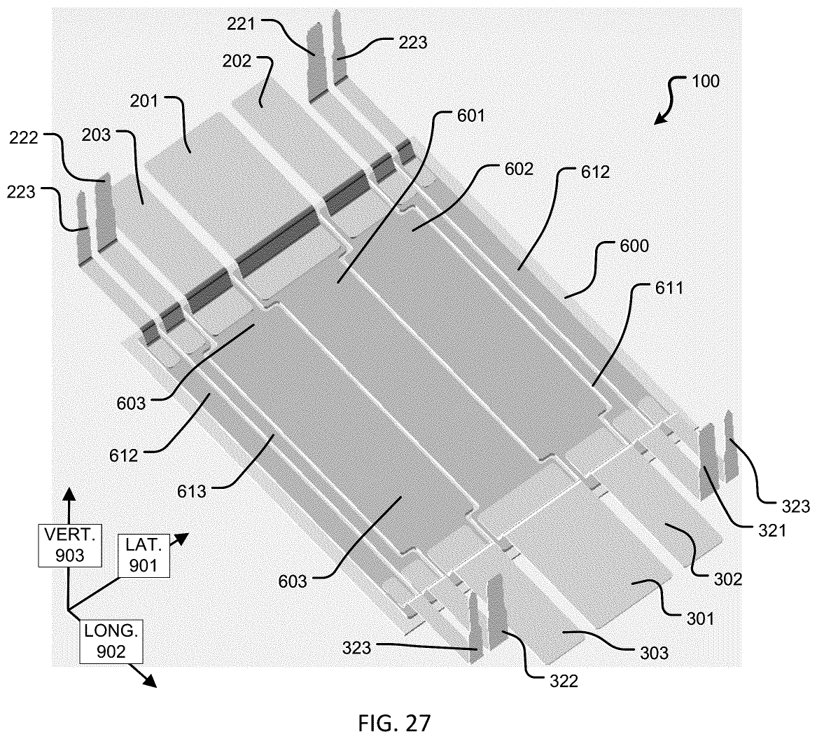

FIG. 27 illustrates a partial perspective view of an exemplary implementation a power module according to aspects of the disclosure.

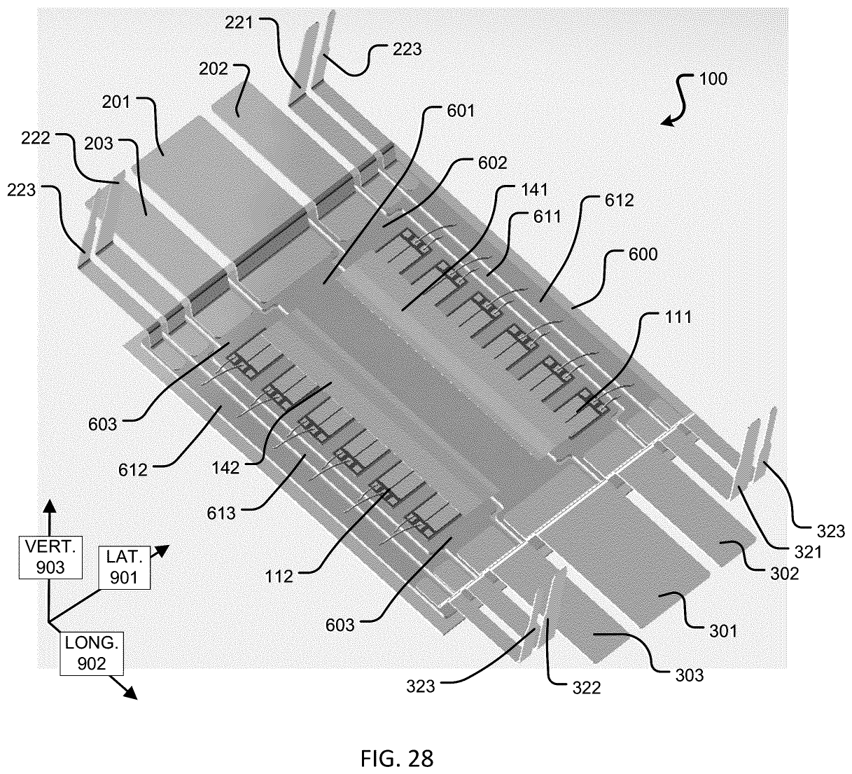

FIG. 28 illustrates a further partial perspective view of the exemplary implementation the power module according to FIG. 27.

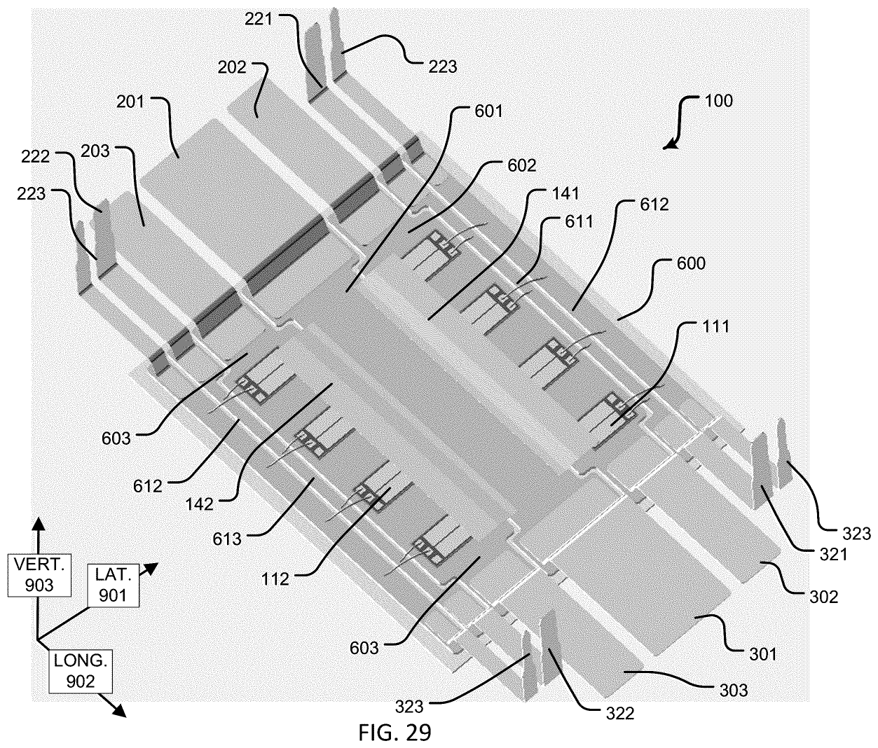

FIG. 29 illustrates a further partial perspective view of the exemplary implementation the power module according to FIG. 27.

Aspects of the power module 100 illustrated in FIG. 27, FIG. 28, and FIG. 29 may optionally include any other features of the power module 100 as described and illustrated herein. Further, aspects of the power module 100 illustrated in FIG. 27, FIG. 28, and FIG. 29 and described therewith may optionally be implemented in any other implementations of the power module 100 as described and illustrated herein.

In aspects, the power module 100 may have two implementations of the third signal terminal 223 and the third signal terminal 323. In aspects, the power module 100 may have two implementations of the second signal trace 612. In aspects, the power module 100 may not implement the fourth power terminal 204 and the fourth power trace 604.

As illustrated in FIG. 27, the power module 100 may be implemented such that the two implementations of the third signal terminal 223 may be arranged on the first power module side 101 on opposing lateral ends of the lateral axis 901 thereof; and the power module 100 may be implemented such that the two implementations of the third signal terminal 323 may be arranged on the second power module side 102 on opposing lateral ends of the lateral axis 901 thereof.

In aspects, the second signal terminal 222 and the first signal terminal 221 may be arranged between the two implementations of the third signal terminal 223; and the second signal terminal 322 and the first signal terminal 321 may be arranged between the two implementations of the third signal terminal 323.

In aspects, the first power terminal 201, the second power terminal 202, and the third power terminal 203 may be arranged between the second signal terminal 222 and the first signal terminal 221; and the first power terminal 301, the second power terminal 302, and the third power terminal 303 may be arranged between the first signal terminal 321 and the second signal terminal 322.

In aspects, the two implementations of the second signal trace 612 may be arranged on the power substrate 600 on opposing lateral ends of the lateral axis 901 thereof. In aspects, the third signal trace 613 and the first signal trace 611 may be arranged between the two implementations of the second signal trace 612. In aspects, the first power trace 601, the second power trace 602, and the third power trace 603 may be arranged between the third signal trace 613 and the first signal trace 611.

FIG. 28 illustrates further details of the power module 100 as previously described herein. FIG. 29 illustrates implementations of the power module 100 having fewer implementations of the at least one first power device 111 and the at least one second power device 112. In this regard, there may be any number of the at least one first power device 111 and the at least one second power device 112 implemented by the power module 100.

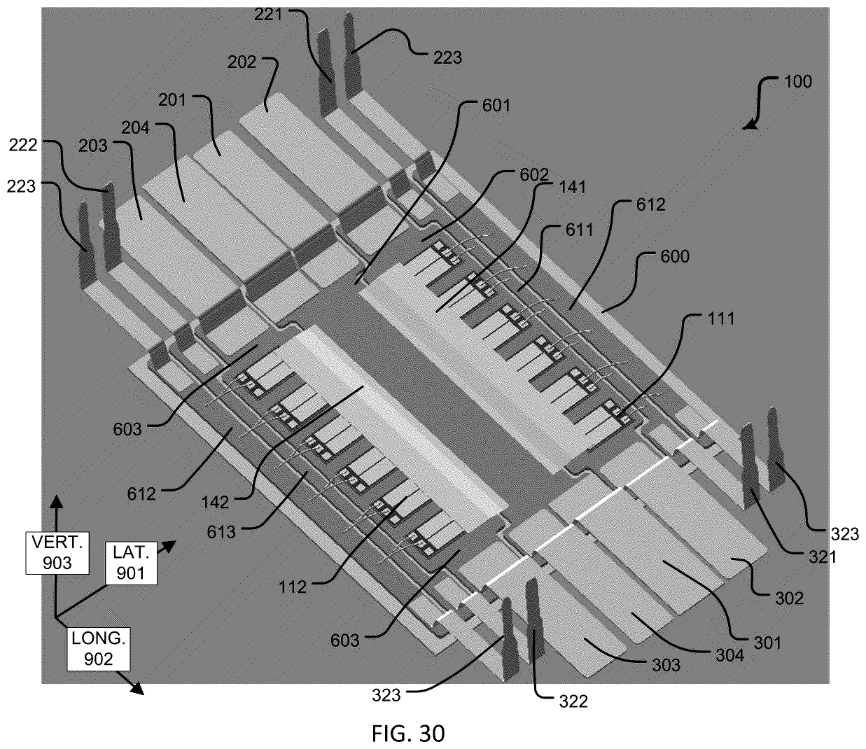

FIG. 30 illustrates a partial perspective view of an exemplary implementation a power module according to aspects of the disclosure.

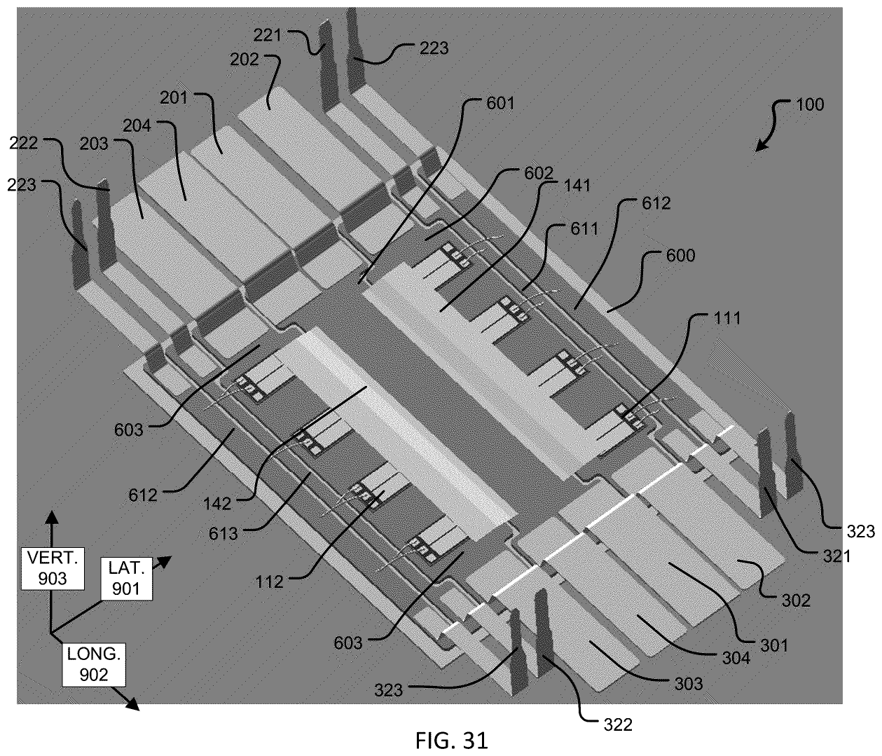

FIG. 31 illustrates a further partial perspective view of the exemplary implementation the power module according to FIG. 30.

Aspects of the power module 100 illustrated in FIG. 30 and FIG. 31, may optionally include any other features of the power module 100 as described and illustrated herein. Further, aspects of the power module 100 illustrated in FIG. 30 and FIG. 31 and described therewith may optionally be implemented in any other implementations of the power module 100 as described and illustrated herein.

In aspects, the power module 100 may have two implementations of the third signal terminal 223 and the third signal terminal 323. In aspects, the power module 100 may have two implementations of the second signal trace 612. In aspects, the power module 100 may not implement the fourth power trace 604.

As illustrated in FIG. 30, the power module 100 may be implemented such that the two implementations of the third signal terminal 223 may be arranged on the first power module side 101 on opposing lateral ends of the lateral axis 901 thereof; and the power module 100 may be implemented such that the two implementations of the third signal terminal 323 may be arranged on the second power module side 102 on opposing lateral ends of the lateral axis 901 thereof.

In aspects, the second signal terminal 222 and the first signal terminal 221 may be arranged between the two implementations of the third signal terminal 223; and the second signal terminal 322 and the first signal terminal 321 may be arranged between the two implementations of the third signal terminal 323.

In aspects, the first power terminal 201, the second power terminal 202, the third power terminal 203, and the fourth power terminal 204 may be arranged between the second signal terminal 222 and the first signal terminal 221; and the first power terminal 301, the second power terminal 302, the third power terminal 303, and the fourth power terminal 304 may be arranged between the first signal terminal 321 and the second signal terminal 322.

FIG. 30 illustrates further details of the power module 100 as previously described herein. FIG. 31 illustrates implementations of the power module 100 having fewer implementations of the at least one first power device 111 and the at least one second power device 112. In this regard, there may be any number of the at least one first power device 111 and the at least one second power device 112 implemented by the power module 100.

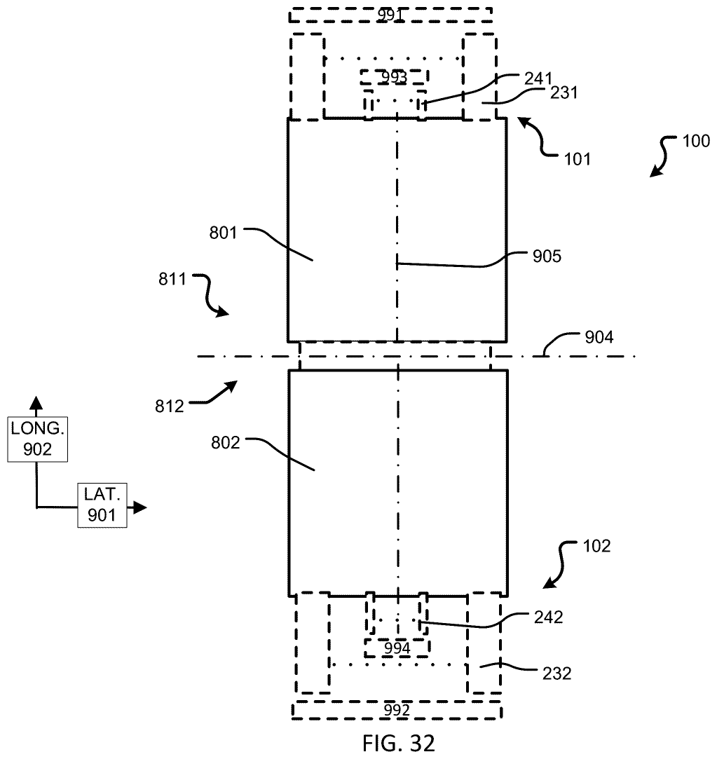

FIG. 32 illustrates a power module implemented with a plurality of power module portions according to aspects of the disclosure.

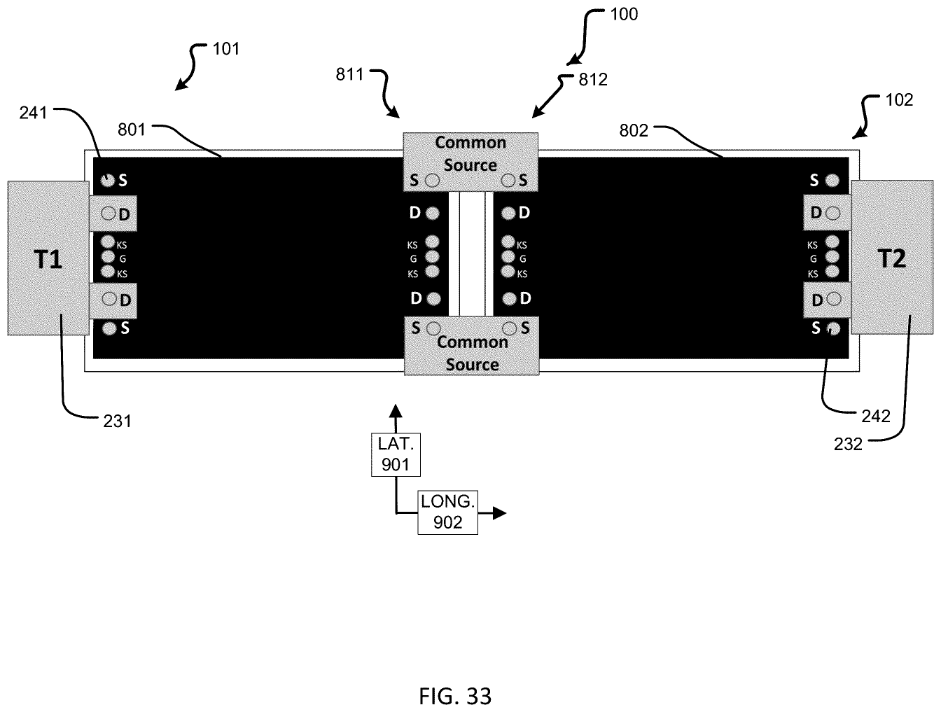

FIG. 33 illustrates an exemplary implementation of the power module of FIG. 32.

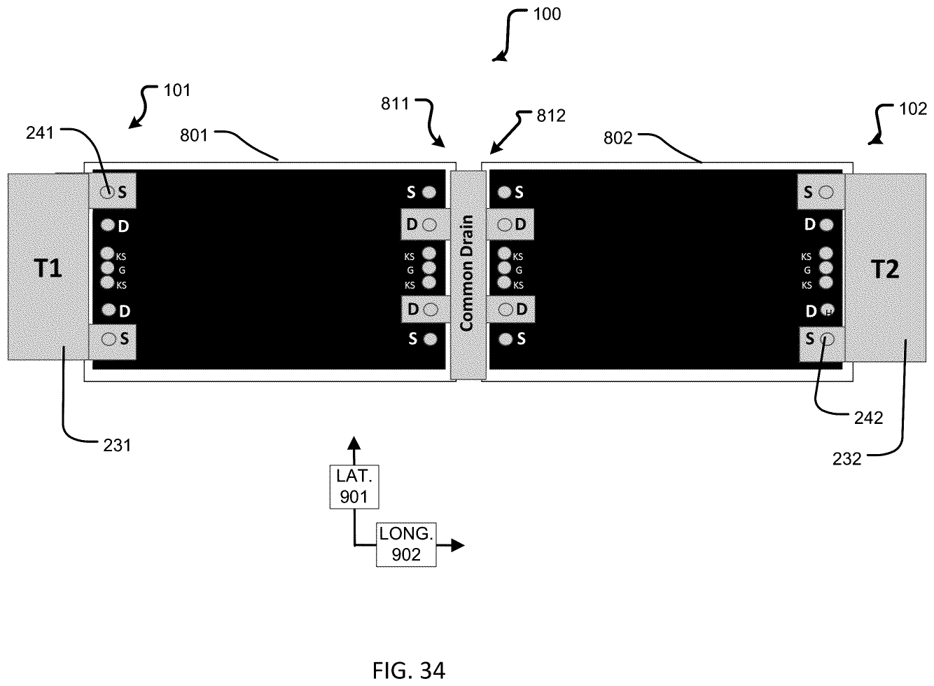

FIG. 34 illustrates another exemplary implementation of the power module of FIG. 32.

Aspects of the power module 100 illustrated in FIG. 32, FIG. 33, and FIG. 34 may optionally include any other features of the power module 100 as described and illustrated herein. Further, aspects of the power module 100 illustrated in FIG. 32, FIG. 33, and FIG. 34 and described therewith may optionally be implemented in any other implementations of the power module 100 as described and illustrated herein.

In particular, FIG. 32 illustrates the power module 100 implemented with at least a first power module portion 801 and a second power module portion 802. In aspects, the first power module portion 801 may be connected to the second power module portion 802. Accordingly, the power module 100 may be configured to provide modularity and scalability by implementation of multiple power module portions.

In aspects, the first power module portion 801 may include the first power terminals 231. In aspects, the first power module portion 801 may further include interconnection power terminals 811.

In aspects, the second power module portion 802 may include the second power terminals 232. In aspects, the second power module portion 802 may further include interconnection power terminals 812.

In aspects, the interconnection power terminals 811 of the first power module portion 801 may connect to the interconnection power terminals 812 of the second power module portion 802. In aspects, the interconnection power terminals 811 of the first power module portion 801 may not be symmetrical with the first power terminals 231. In aspects, the interconnection power terminals 812 of the second power module portion 802 may not be symmetrical with the second power terminals 232.

In aspects, the interconnection power terminals 811 of the first power module portion 801 and the interconnection power terminals 812 of the second power module portion 802 may be common source terminals. In aspects, the common source terminal implementations of the interconnection power terminals 811 of the first power module portion 801 and the interconnection power terminals 812 of the second power module portion 802 may be configured to be connected.

In aspects, the interconnection power terminals 811 of the first power module portion 801 and the interconnection power terminals 812 of the second power module portion 802 may be common drain terminals. In aspects, the common drain terminal implementations of the interconnection power terminals 811 of the first power module portion 801 and the interconnection power terminals 812 of the second power module portion 802 may be configured to be connected.

In aspects, the first power module portion 801 and the second power module portion 802 may have the same configuration. In aspects, the first power module portion 801 and the second power module portion 802 may have a different configuration.

In aspects, the first signal terminals 241 and the first power terminals 231 may be arranged on the first power module portion 801. In aspects, the second signal terminals 242 and the second power terminals 232 may be arranged on the second power module portion 802. Further, the power module 100 may implement any type of connections between the first power module portion 801 and the second power module portion 802.

In aspects, an arrangement and location of the first power terminals 231 on the first power module portion 801 may be symmetrical about the lateral axis of symmetry 904 with respect to an arrangement and location the second power terminals 232 on the second power module portion 802.

In aspects, an arrangement and location of the first signal terminals 241 on the first power module portion 801 may be symmetrical about the lateral axis of symmetry 904 with respect to an arrangement and location the second signal terminals 242 on the second power module portion 802.

In aspects, an arrangement and location of the first power terminals 231 on the first power module portion 801 may be symmetrical about the longitudinal axis of symmetry 905 with respect to an arrangement and location the second power terminals 232 on the second power module portion 802.

In aspects, an arrangement and location of the first signal terminals 241 on the first power module portion 801 may be symmetrical about the longitudinal axis of symmetry 905 with respect to an arrangement and location the second signal terminals 242 on the second power module portion 802.

FIG. 33 illustrates an exemplary implementation of the power module 100 of FIG. 32. In this regard, the first power module portion 801 may implement a single implementation of the first power terminals 231; and the second power module portion 802 may implement a single implementation of the second power terminals 232. The connections between the first power module portion 801 and the second power module portion 802 may be common source connections.

FIG. 34 illustrates an exemplary implementation of the power module 100 of FIG. 32. In this regard, the first power module portion 801 may implement a single implementation of the first power terminals 231; and the second power module portion 802 may implement a single implementation of the second power terminals 232. The connections between the first power module portion 801 and the second power module portion 802 may be common drain connections.

In aspects of the disclosure, the power module 100 may be configured for significant amounts of modularity and scalability. The power module 100 may be scaled to match industry standard footprints to be compatible with series, parallel, common-source, common-drain, and/or the like interconnections.

In aspects of the disclosure, the power module 100 may be configured such that: a layout and structure of a high-current symmetric pin-out single switch position power module may be implemented in common-source or common-drain connections externally; a layout and structure of a high-current symmetric pin-out multi switch position power module may have a common-source, a common-drain, and/or the like connection internally; a layout and structure that may be compatible with multiple internal interconnection methods, such as one or more wire bonds, ribbons, clips, and/or the like; a layout and structure that may be compatible with single sided, double sided cooling, and/or the like; terminal arrangements that may include signal pins on the inside and power pins on the outside; terminal arrangements with power pins on the inside and signal pins on the outside; terminal arrangements with interleaved power and signal pins; terminal structures that may enhance end to end interconnection with strain relief; a modular layout which may house multiple device types, devices sizes, physical arrangements, and/or the like; a scalable structure such that a length and a width may be configured to adapt to a given size to meet footprint requirements, to optimize power density, and/or the like; a scalable structure such that a length and a width can be configured to adapt to optimize heat spreading, thermal performance, and/or the like; a layout and structure configured to implement additional functionality such as temperature sensors, current sensors, strain sensors, and/or the like; and a structure configured to be compatible with multiple power module implementations, including a case module with or without base plate, an over molded module with or without base plate, and/or the like.

Aspects of the power module 100 may be configured to implement techniques for realizing a common-source, a common-drain, and/or the like bidirectional switch topologies with the single switch module; and techniques for paralleling the common-source and common-drain modules.

In aspects of the disclosure, the power module 100 may be configured such that in many applications, power modules may be used with a relatively small number of power devices, such as one to four power devices. These power modules can then be used as building blocks to scale up or down to the desired output current and/or the like. Thereafter, the power modules may be arranged to form the desired topology. For example, six single switch packages could be arranged to form a three-phase topology that may implement three bridge legs. If twice the output power is desired, twelve packages may be arranged to form the same topology with paralleled packages for each bridge leg.

This high level of modularity allows customers with a variety of end use power levels and applications to adopt the same module for all of their systems. Often, however, this comes at the cost of system complexity due to the number of parts, and reduced power density due to placement and tolerance.

In aspects of the disclosure, the power module 100 may be configured to have the capability to meet the needs of many applications in a way that can be compact and maintain the flexibility of multiple package approaches, while also being able to scale up to house a large number of power devices in a single housing. Further, the modular and scalable reversible module of the disclosure may also be configured to form a topology, or arrangement of devices, in a manner best suited for the target application.

In aspects of the disclosure, the power module 100 may have a symmetrical pinout. In aspects, the pins may be identical on either side of the power module 100. In aspects, this may allow for the power modules to the placed end to end to scale up to a given power level, to allow for interconnection to form a topology, and/or the like. Other terminal arrangements are possible, with the opposite side matching for symmetry.

As described and illustrated herein, the power module may be configured with numerous devices, such as twelve devices for each switch position, in two symmetrical rows. The power devices may be paralleled. Moreover, connection leads may be placed in a symmetric manner. The number of devices may be increased or decreased internally, or the packages could be readily paralleled externally. This symmetry may allow for the power module 100 to cater to multiple applications.

As described and illustrated herein, the power module 100 may be configured with physical arrangements to form topologies to be reversible. As an example, commercial electrical vehicle manufacturers may use standalone or paralleled implementations of the power module 100 in high-power applications such traction motor drives, onboard battery chargers, and/or the like. These power modules might require unidirectional or bidirectional current flow capabilities, depending on the topology.

As another example three level inverter topologies such a T-Type inverter may allow for less distortion of the output current requiring less filtering to achieve a clean output signal. A reversible implementation of the power module 100 as described and illustrated herein, may be utilized in all the aforementioned topologies. For example, the power module 100 may be configured with a common-source, a common-drain, and/or like connections being made external to the power module 100 as needed. In aspects, a symmetry in the external leads of the power module 100 may lend itself to easier connections. Accordingly, implementations of the power module 100 when connected in a bidirectional topology man be able to block voltages and conduct currents in both directions, while maintaining low on-resistance and maximizing efficiency.

In the disclosed implementation the power module 100, a power loop may be from the drain lead to the source lead. There may be two signal loops for each implementation of plurality of power devices 130, the at least one first power device 111, and/or the at least one second power device 112, each from their individual gates to the common source node. Depending on how the device will be used, the importance of the signal loop must be considered. For a circuit breaker, the associated devices may be running in the on-state for the majority of the operational time. Here, switching efficiency and quality may be less significant. Hence, the power loop impedance may be less significant. However, in a switching application, such as in an inverter, switching events may occur often so efficiency and quality may be of high importance, with an according importance in the power loop impedance.

In aspects, the power module 100 as disclosed may be configured such that drain-source (or collector-emitter) and gate-source (or gate-emitter) loops may share a same connection at the source (or emitter) of the power module 100. If the power path couples into the signal paths, extra dynamics may be introduced through either positive or negative feedback. Typically, negative feedback may introduce extra losses as the power path coupling fights the control signal (i.e. the power path coupling tries to turn the device off when the control signal is trying to turn the device on). Positive feedback typically causes instability as the power path coupling amplifies the control signal until the devices are destroyed. Ultimately, the coupling of power and signal paths may result in a reduction in switching quality, slower switching speeds, increased losses, and possible destruction.

Accordingly, aspects of the power module 100 may be configured to improve switching quality and may implement independent loops. Here, the power source connection may have a separate path from the signal source (referred to as a Kelvin source) such that one does not overlap or interfere with the other. The closer the separate connections are made to the plurality of power devices 130, the at least one first power device 111, and/or the at least one second power device 112, the better the switching performance may be.

Accordingly, aspects of the power module 100 may be configured such that the loops may be completely independent, this is referred as a ‘true kelvin’ connection. This may be achieved with symmetrical layouts by having additional pins for the signals such that the module can be rotated 180 degrees and the neighboring pins match the same pinout. If a pin is in the middle of the module, it does not need to be duplicated.

Accordingly, aspects of the power module 100 may be configured such that a presence of external leads for all terminals can be leveraged to realize common-source and/or common-drain connections for various applications. The presence of external leads can be employed to access the common node for purposes of protection circuitry such as DESAT, a current shunt, a Rogowski coil, and/or the like.

Accordingly, aspects of the power module 100 may be configured as a universal module, which provides paralleled die in a single housing with completely symmetric power and signal loop pins. In aspects, an advantage of the power module 100 configuration is that the power module 100 may be used as a single switch or coupled with other such modules to realize common-source and/or common-drain topology. Furthermore, as required by applications, the power modules may be connected in series and/or paralleled. In aspects, a single footprint implementation of the power module 100 for all the above mentioned circuit options may result in a power module that can be used ubiquitously.

Aspects of the power module 100 may be encapsulated through over molding or using other materials such as ceramic frames with silica gel, epoxy-resin, etc. Aspects of the power module 100 may include staggered pinouts and/or terminals that may enable easy series/parallel connection of modules.

Aspects of the power module 100 may: include implementations with single-side cooled module topologies; wide power ribbons configured with horizontal fanout around outer border; narrow signal ribbons configured with vertical fanout along central line; one or more metallic clips connecting to a power source to reduce wire bonds; configured to be Scalable in size and accommodate multiple chips of various sizes, shapes; as a single switch that may be connected externally in various topologies such as—series topologies, parallel topologies, anti-series topologies, common-source topologies, common-drain topologies, and/or the like; and/or configured to adopt various applications including switching intensive applications, normally-on applications, and/or the like.

Aspects of the power module 100 may: be configured with power terminals arranged along outer border and signal pinouts along center; be configured with vertically staggered ribbons for easy module interconnection; implement metallic clips for connecting power source to reduce wire bonds; the configured to be scalable in size and accommodate multiple chips of various sizes, shapes; configured as a single switch that may be connected externally in various topologies—series topologies, parallel topologies, anti-series topologies, common-source topologies, common-drain topologies, and/or the like; and/or be configured to adopt for various applications including switching intensive applications, normally-on applications, as lessor the like.

Aspects of the power module 100 may: configured with a common-source bidirectional switch topology; configured with a split drain pad that allows grouping devices into common-drain topology; configured such that all devices may be driven through the gate signal in the center rail; configured with narrow signal ribbons implementing a vertical fanout along central line; configured with metallic clips connecting power source to reduce wire bonds; configured such that a number of devices may be adjusted to cater to different power ratings; and/or configured with two gate signal rails in the center and two bidirectional switches that can be functionally separated.

Aspects of the power module 100 may: configured with a common-source bidirectional switch topology; configured with vertically staggered ribbons for easy module interconnection; configured such that all devices driven through the gate signal in the center rail; configured with narrow signal ribbons having a vertical fanout along central line; configured with metallic clips connecting power source to reduce wire bonds; configured with a number of devices that may be adjusted to cater to different power ratings; and/or configured with two gate signal rails in the center and two bidirectional switches that may be functionally separated.

Aspects of the power module 100 may: configured as a common-drain bidirectional switch; configured with narrow signal ribbons implementing vertical fanout along central line; configured with metallic clips connecting a power source to reduce wire bonds; configured such that a number of devices may be adjusted to cater to different power ratings; configured with two gate signal rails in the center and two bidirectional switches can be functionally separated.

Aspects of the power module 100 may be: configured as a common-drain bidirectional switch; configured with vertically staggered ribbons for easy module interconnection; configured with narrow signal ribbons having a vertical fanout along central line; configured with metallic clips connecting to a power source to reduce wire bonds; configured such that a number of devices may be adjusted to cater to different power ratings; and/or configured with two gate signal rails in the center and two bidirectional switches that may be functionally separated.

The plurality of power devices 130, the at least one first power device 111, and/or the at least one second power device 112 may be implemented as one or more of the power semiconductor devices, a wide band-gap semiconductor device, an ultra-wideband device, a GaN based device, a LDMOS (Laterally-Diffused Metal-Oxide Semiconductor) device, a Metal Semiconductor Field-Effect Transistor (MESFET), a Metal Oxide Field Effect Transistor (MOSFET), a power MOSFET, a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a diode, a power Schottky diode, a gate-controlled thyristor, a Metal Insulator Semiconductor Field Effect Transistor (MISFET), and/or the like. The plurality of power devices 130, the at least one first power device 111, and/or the at least one second power device 112 may include a semiconductor layer structure that is formed using, for example, silicon and/or wide bandgap semiconductor materials such as silicon carbide and/or gallium nitride-based and/or aluminum nitride-based semiconductor systems (e.g., GaN, AlGaN, InGaN, AlN, etc.). Other wide bandgap materials may be used such as devices formed in other Group III-V semiconductor systems or in Group II-VI semiconductor systems.

A power semiconductor device may refer to devices that include one or more power semiconductor die that are designed to carry large currents and/or that are capable of blocking high voltages. Herein, a power semiconductor die refers to a semiconductor die that during normal operation can pass at least one Amp of current and/or block at least one hundred volts during reverse blocking operation. Power semiconductor die may be fabricated from wide bandgap semiconductor materials, such as silicon carbide (“SiC”) or gallium nitride (“GaN”) based semiconductor materials. A wide variety of power semiconductor die are known in the art, including, for example, power Metal Oxide Semiconductor Field Effect Transistors (“MOSFETs”), power insulated gate bipolar junction transistors (“IGBTs”), power Schottky diodes, and/or the like. Power semiconductor die are often packaged to provide a packaged power semiconductor device.

In aspects, the power substrate 600 may be implemented as a power substrate that includes a ceramic substrate. In aspects, the power substrate may include a lower metal cladding layer formed on a lower side of the ceramic substrate, and an upper metal cladding layer may be formed on the upper side of the ceramic substrate. As used herein, the term “power substrate” refers to a dielectric substrate that has a metal cladding layer on both sides thereof. In aspects, the power substrate may be an Active Metal Brazed (AMB) power substrate, which includes first and second metal braze layers that may be used to bond first and second metal cladding layers, respectively, to the ceramic substrate. In aspects, the power substrate may be a Substrate (or, more typically, a Direct Bonded Copper (DBC) power substrate, as the metal cladding layers may typically be copper layers).

The power module 100 may include a base plate. The base plate may provide structural support to the power module 100 as well as facilitating heat spreading for thermal management of the power module 100. The base plate may include a base metal, such as copper, aluminum, or the like, or a metal matrix composite (MMC) which may provide coefficient of thermal expansion (CTE) matching to reduce thermally generated stress. In one aspect, the MMC material may be a composite of a high conductivity metal such as copper, aluminum, and the like, and either a low CTE metal such as molybdenum, beryllium, tungsten, and/or a nonmetal such as diamond, silicon carbide, beryllium oxide, graphite, embedded pyrolytic graphite, or the like. Depending on the material, the base plate may be formed by machining, casting, stamping, or the like. The base plate may have a metal plating, such as nickel, silver, gold and/or the like, to protect surfaces of the base plate and improve solder-ability. In one aspect, the base plate may have a flat backside. In one aspect, the base plate may have a convex profile to improve planarity after reflow. In one aspect, the base plate may have pin fins for direct cooling.

In one aspect, the power module 100 may be implemented in a wide variety of power topologies, including half-bridge, full-bridge, three phase, booster, chopper, DC-DC converters, and like arrangements and/or topologies. In one aspect, one or more implementations of the power module 100 may be implemented in an application.

The application may be a power system, a motor system, a motor drive, an automotive motor system, a charging system, an automotive charging system, a vehicle system, an industrial motor drive, an embedded motor drive, an uninterruptible power supply, an AC-DC power supply, a welder power supply, a military system, an inverter, an inverter for wind turbines, solar power panels, tidal power plants, electric vehicles (EVs), a converter, a solar inverter, a circuit breaker, a protection circuit, a DC-DC converter, an Off-Board DC Fast Charger for an electric vehicle (EV), an on-board DC/DC Converter for an electric vehicle (EV), an on-board battery charger for an electric vehicle (EV), an electric vehicle (EV) Powertrain/Main Inverter, an electric vehicle (EV) charging infrastructure, an electric traction motor, a motor drive for an electric motor, a commercial inductive heating system, an uninterruptible power system, a power system, a motor system, a motor drive, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, electric vehicles (EVs), a converter, solar inverters, circuit breakers, protection circuits, DC-DC converters, Off-Board DC Fast Chargers for electric vehicles (EVs) and the like, on-board DC/DC Converters for electric vehicles (EVs) and the like, on-board battery chargers for electric vehicles (EVs) and the like, electric vehicle (EV) Powertrains/Main Inverters, electric vehicle (EV) charging infrastructures, electric traction motors, motor drives for electric motors, commercial inductive heating systems, uninterruptible power systems, and/or the like.

Accordingly, the disclosure has provided a power module having an improved configuration.

The following are a number of nonlimiting EXAMPLES of aspects of the disclosure.

One EXAMPLE: a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where a location of the first power terminals on the first power package side is symmetrical with respect to a location of the second power terminals on the second power package side.

The above-noted EXAMPLE may further include any one or a combination of more than one of the following EXAMPLES:

The power package includes where a location of the first power terminals on the first power package side is symmetrical with respect to one side of the first power package side and another side of the first power package side; and where a location of the second power terminals on the second power package side is symmetrical with respect to one side of the second power package side and another side of the second power package side. The power package also includes where a location of the first signal terminals on the first power package side is symmetrical with respect to a location of the second signal terminals on the second power package side. The power package further includes where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The power package in addition includes where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package moreover includes where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections. The power package also includes where the first signal terminals may include one or more source kelvin terminals, gate terminals, and/or sensor terminals; and where the second signal terminals may include one or more source kelvin terminals, gate terminals, and/or sensor terminals. The power package further includes where the first signal terminals are arranged on the first power package side between implementations of the first power terminals; and where the second signal terminals are arranged on the second power package side between implementations of the second power terminals. The power package in addition includes where the first power terminals are arranged on the first power package side between implementations of the first signal terminals; and where the second power terminals are arranged on the second power package side between implementations of the second signal terminals. The power package moreover includes may include: a power substrate; at least one power trace arranged on the power substrate; and at least one signal trace arranged on the power substrate. The power package also includes where the at least one power trace may include a plurality of implementations of the at least one power trace. The power package further includes where the at least one signal trace may include one or more kelvin source traces, gate traces, and/or sensor traces. The power package in addition includes where the at least one signal trace may include a plurality of implementations of the at least one signal trace. The power package moreover includes where the plurality of implementations of the at least one signal trace may include a plurality of kelvin source traces and/or gate traces. The power package also includes where the at least one power trace may include one or more power device drain traces and/or power device source traces. The power package further includes where the at least one power trace may include a plurality of power traces having a plurality of power device drain traces and/or power device source traces. The power package in addition includes where the first power terminals and the second power terminals are configured to connect to the at least one power trace. The power package moreover includes where the first signal terminals and the second signal terminals are configured to connect to the at least one signal trace. The power package also includes may include a plurality of power devices, where the plurality of power devices are arranged on one or more implementations of the at least one power trace. The power package further includes where a location of the plurality of power devices, the at least one signal trace, the at least one power trace, and/or the power substrate are symmetrical about a lateral axis of symmetry. The power package in addition includes where a location of the plurality of power devices, the at least one signal trace, the at least one power trace, and/or the power substrate are symmetrical about a longitudinal axis of symmetry. The power package moreover includes where the first power terminals are configured to connect to respective first power connections of an application; where the second power terminals are configured to connect to respective second power connections of an application; where the plurality of power devices, the at least one signal trace, the at least one power trace, and/or the power substrate are configured to operate in a manner when the first power terminals connect to the respective first power connections and the second power terminals connect to the respective second power connections; and where the plurality of power devices, the at least one signal trace, the at least one power trace, and/or the power substrate are configured to operate in a same manner when the first power terminals connect to the respective second power connections and the second power terminals connect to the respective first power connections. The power package also includes where the plurality of power devices may include at least one first power device and at least one second power device; where the at least one power trace may include a first power trace, a second power trace, a third power trace, and a fourth power trace; where the at least one first power device is arranged on and attached to the second power trace; and where the at least one second power device is arranged on and attached to the third power trace. The power package further includes where the first power terminals, the second power terminals, the first signal terminals, the second signal terminals, the plurality of power devices, the at least one signal trace, the at least one power trace, and/or the power substrate are configured, structured, arranged, and/or implemented such that the power package implements a standalone configuration, a paralleled configuration, a common-source bidirectional configuration, and/or a common-drain bidirectional configuration. The power package in addition includes where the first power terminals may include a first power terminal, a second power terminal, a third power terminal, and a fourth power terminal; and where the second power terminals may include a first power terminal, a second power terminal, a third power terminal, and a fourth power terminal. The power package moreover includes where the first signal terminals may include a first signal terminal, a second signal terminal, and a third signal terminal; and where the second signal terminals may include a first signal terminal, a second signal terminal, and a third signal terminal. The power package also includes may include at least a first power package portion and a second power package portion, where the first power package portion may include the first power terminals; where the first power package portion further may include interconnection power terminals; where the second power package portion may include the second power terminals; and where the second power package portion further may include interconnection power terminals. The power package further includes where the interconnection power terminals of the first power package portion are configured to connect to the interconnection power terminals of the second power package portion. The power package in addition includes where the interconnection power terminals of the first power package portion and the interconnection power terminals of the second power package portion may include common source terminals. The power package moreover includes where the interconnection power terminals of the first power package portion and the interconnection power terminals of the second power package portion may include common drain terminals.

One EXAMPLE: a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where a location of the first signal terminals on the first power package side is symmetrical with respect to a location of the second signal terminals on the second power package side.

The above-noted EXAMPLE may further include any one or a combination of more than one of the following EXAMPLES:

The power package includes where a location of the first power terminals on the first power package side is symmetrical with respect to one side of the first power package side and another side of the first power package side; and where a location of the second power terminals on the second power package side is symmetrical with respect to one side of the second power package side and another side of the second power package side. The power package also includes where a location of the first signal terminals on the first power package side is symmetrical with respect to a location of the second signal terminals on the second power package side. The power package further includes where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The power package in addition includes where a location of the first power terminals on the first power package side is symmetrical with respect to a location of the second power terminals on the second power package side. The power package moreover includes where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package also includes where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections. The power package further includes where the first signal terminals may include one or more source kelvin terminals, gate terminals, and/or sensor terminals; and where the second signal terminals may include one or more source kelvin terminals, gate terminals, and/or sensor terminals. The power package in addition includes where the first signal terminals are arranged on the first power package side between implementations of the first power terminals; and where the second signal terminals are arranged on the second power package side between implementations of the second power terminals. The power package moreover includes where the first power terminals are arranged on the first power package side between implementations of the first signal terminals; and where the second power terminals are arranged on the second power package side between implementations of the second signal terminals. The power package also includes may include: a power substrate; at least one power trace arranged on the power substrate; and at least one signal trace arranged on the power substrate. The power package further includes where the at least one power trace may include a plurality of implementations of the at least one power trace. The power package in addition includes where the at least one signal trace may include one or more kelvin source traces, gate traces, and/or sensor traces. The power package moreover includes where the at least one signal trace may include a plurality of implementations of the at least one signal trace. The power package also includes where the plurality of implementations of the at least one signal trace may include a plurality of kelvin source traces and/or gate traces. The power package further includes where the at least one power trace may include one or more power device drain traces and/or power device source traces. The power package in addition includes where the at least one power trace may include a plurality of power traces having a plurality of power device drain traces and/or power device source traces. The power package moreover includes where the first power terminals and the second power terminals are configured to connect to the at least one power trace. The power package also includes where the first signal terminals and the second signal terminals are configured to connect to the at least one signal trace. The power package further includes may include a plurality of power devices, where the plurality of power devices are arranged on one or more implementations of the at least one power trace. The power package in addition includes where a location of the plurality of power devices, the at least one signal trace, the at least one power trace, and/or the power substrate are symmetrical about a lateral axis of symmetry. The power package moreover includes where a location of the plurality of power devices, the at least one signal trace, the at least one power trace, and/or the power substrate are symmetrical about a longitudinal axis of symmetry. The power package also includes where the first power terminals are configured to connect to respective first power connections of an application; where the second power terminals are configured to connect to respective second power connections of an application; where the plurality of power devices, the at least one signal trace, the at least one power trace, and/or the power substrate are configured to operate in a manner when the first power terminals connect to the respective first power connections and the second power terminals connect to the respective second power connections; and where the plurality of power devices, the at least one signal trace, the at least one power trace, and/or the power substrate are configured to operate in a same manner when the first power terminals connect to the respective second power connections and the second power terminals connect to the respective first power connections. The power package further includes where the plurality of power devices may include at least one first power device and at least one second power device; where the at least one power trace may include a first power trace, a second power trace, a third power trace, and a fourth power trace; where the at least one first power device is arranged on and attached to the second power trace; and where the at least one second power device is arranged on and attached to the third power trace. The power package in addition includes where the first power terminals, the second power terminals, the first signal terminals, the second signal terminals, the plurality of power devices, the at least one signal trace, the at least one power trace, and/or the power substrate are configured, structured, arranged, and/or implemented such that the power package implements a standalone configuration, a paralleled configuration, a common-source bidirectional configuration, and/or a common-drain bidirectional configuration. The power package moreover includes where the first power terminals may include a first power terminal, a second power terminal, a third power terminal, and a fourth power terminal; and where the second power terminals may include a first power terminal, a second power terminal, a third power terminal, and a fourth power terminal. The power package also includes where the first signal terminals may include a first signal terminal, a second signal terminal, and a third signal terminal; and where the second signal terminals may include a first signal terminal, a second signal terminal, and a third signal terminal. The power package further includes may include at least a first power package portion and a second power package portion, where the first power package portion may include the first power terminals; where the first power package portion further may include interconnection power terminals; where the second power package portion may include the second power terminals; and where the second power package portion further may include interconnection power terminals. The power package in addition includes where the interconnection power terminals of the first power package portion are configured to connect to the interconnection power terminals of the second power package portion. The power package moreover includes where the interconnection power terminals of the first power package portion and the interconnection power terminals of the second power package portion may include common source terminals. The power package also includes where the interconnection power terminals of the first power package portion and the interconnection power terminals of the second power package portion may include common drain terminals.

One EXAMPLE: a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where a location of the first signal terminals on the first power package side is symmetrical with respect to one side of the first power package side and another side of the first power package side. The power package furthermore includes where a location of the second signal terminals on the second power package side is symmetrical with respect to one side of the second power package side and another side of the second power package side.

The above-noted EXAMPLE may further include any one or a combination of more than one of the following EXAMPLES:

The power package includes where a location of the first power terminals on the first power package side is symmetrical with respect to a location of the second power terminals on the second power package side. The power package also includes where a location of the first signal terminals on the first power package side is symmetrical with respect to a location of the second signal terminals on the second power package side. The power package further includes where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The power package in addition includes where a location of the first power terminals on the first power package side is symmetrical with respect to a location of the second power terminals on the second power package side; and where a location of the first power terminals on the first power package side is symmetrical with respect to one side of the first power package side and another side of the first power package side; and where a location of the second power terminals on the second power package side is symmetrical with respect to one side of the second power package side and another side of the second power package side. The power package moreover includes where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package also includes where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections. The power package further includes where the first signal terminals may include one or more source kelvin terminals, gate terminals, and/or sensor terminals; and where the second signal terminals may include one or more source kelvin terminals, gate terminals, and/or sensor terminals. The power package in addition includes where the first signal terminals are arranged on the first power package side between implementations of the first power terminals; and where the second signal terminals are arranged on the second power package side between implementations of the second power terminals. The power package moreover includes where the first power terminals are arranged on the first power package side between implementations of the first signal terminals; and where the second power terminals are arranged on the second power package side between implementations of the second signal terminals. The power package also includes may include: a power substrate; at least one power trace arranged on the power substrate; and at least one signal trace arranged on the power substrate. The power package further includes where the at least one power trace may include a plurality of implementations of the at least one power trace. The power package in addition includes where the at least one signal trace may include one or more kelvin source traces, gate traces, and/or sensor traces. The power package moreover includes where the at least one signal trace may include a plurality of implementations of the at least one signal trace. The power package also includes where the plurality of implementations of the at least one signal trace may include a plurality of kelvin source traces and/or gate traces. The power package further includes where the at least one power trace may include one or more power device drain traces and/or power device source traces. The power package in addition includes where the at least one power trace may include a plurality of power traces having a plurality of power device drain traces and/or power device source traces. The power package moreover includes where the first power terminals and the second power terminals are configured to connect to the at least one power trace. The power package also includes where the first signal terminals and the second signal terminals are configured to connect to the at least one signal trace. The power package further includes may include a plurality of power devices, where the plurality of power devices are arranged on one or more implementations of the at least one power trace. The power package in addition includes where a location of the plurality of power devices, the at least one signal trace, the at least one power trace, and/or the power substrate are symmetrical about a lateral axis of symmetry. The power package moreover includes where a location of the plurality of power devices, the at least one signal trace, the at least one power trace, and/or the power substrate are symmetrical about a longitudinal axis of symmetry. The power package also includes where the first power terminals are configured to connect to respective first power connections of an application; where the second power terminals are configured to connect to respective second power connections of an application; where the plurality of power devices, the at least one signal trace, the at least one power trace, and/or the power substrate are configured to operate in a manner when the first power terminals connect to the respective first power connections and the second power terminals connect to the respective second power connections; and where the plurality of power devices, the at least one signal trace, the at least one power trace, and/or the power substrate are configured to operate in a same manner when the first power terminals connect to the respective second power connections and the second power terminals connect to the respective first power connections. The power package further includes where the plurality of power devices may include at least one first power device and at least one second power device; where the at least one power trace may include a first power trace, a second power trace, a third power trace, and a fourth power trace; where the at least one first power device is arranged on and attached to the second power trace; and where the at least one second power device is arranged on and attached to the third power trace. The power package in addition includes where the first power terminals, the second power terminals, the first signal terminals, the second signal terminals, the plurality of power devices, the at least one signal trace, the at least one power trace, and/or the power substrate are configured, structured, arranged, and/or implemented such that the power package implements a standalone configuration, a paralleled configuration, a common-source bidirectional configuration, and/or a common-drain bidirectional configuration. The power package moreover includes where the first power terminals may include a first power terminal, a second power terminal, a third power terminal, and a fourth power terminal; and where the second power terminals may include a first power terminal, a second power terminal, a third power terminal, and a fourth power terminal. The power package also includes where the first signal terminals may include a first signal terminal, a second signal terminal, and a third signal terminal; and where the second signal terminals may include a first signal terminal, a second signal terminal, and a third signal terminal. The power package further includes may include at least a first power package portion and a second power package portion, where the first power package portion may include the first signal terminals; where the first power package portion further may include interconnection power terminals; where the second power package portion may include the second signal terminals; and where the second power package portion further may include interconnection power terminals. The power package in addition includes where the interconnection power terminals of the first power package portion are configured to connect to the interconnection power terminals of the second power package portion. The power package moreover includes where the interconnection power terminals of the first power package portion and the interconnection power terminals of the second power package portion may include common source terminals. The power package also includes where the interconnection power terminals of the first power package portion and the interconnection power terminals of the second power package portion may include common drain terminals.

One EXAMPLE: a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where a location of the first signal terminals on the first power package side is symmetrical with respect to a location of the second signal terminals on the second power package side.

The above-noted EXAMPLE may further include any one or a combination of more than one of the following EXAMPLES:

The power package includes where a location of the first power terminals on the first power package side is symmetrical with respect to one side of the first power package side and another side of the first power package side; and where a location of the second power terminals on the second power package side is symmetrical with respect to one side of the second power package side and another side of the second power package side. The power package also includes where a location of the first power terminals on the first power package side is symmetrical with respect to a location of the second power terminals on the second power package side. The power package further includes where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The power package in addition includes where a location of the first power terminals on the first power package side is symmetrical with respect to a location of the second power terminals on the second power package side; and where a location of the first power terminals on the first power package side is symmetrical with respect to one side of the first power package side and another side of the first power package side; and where a location of the second power terminals on the second power package side is symmetrical with respect to one side of the second power package side and another side of the second power package side. The power package moreover includes where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The power package also includes where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections. The power package further includes where the first signal terminals may include one or more source kelvin terminals, gate terminals, and/or sensor terminals; and where the second signal terminals may include one or more source kelvin terminals, gate terminals, and/or sensor terminals. The power package in addition includes where the first signal terminals are arranged on the first power package side between implementations of the first power terminals; and where the second signal terminals are arranged on the second power package side between implementations of the second power terminals. The power package moreover includes where the first power terminals are arranged on the first power package side between implementations of the first signal terminals; and where the second power terminals are arranged on the second power package side between implementations of the second signal terminals. The power package also includes may include: a power substrate; at least one power trace arranged on the power substrate; and at least one signal trace arranged on the power substrate. The power package further includes where the at least one power trace may include a plurality of implementations of the at least one power trace. The power package in addition includes where the at least one signal trace may include one or more kelvin source traces, gate traces, and/or sensor traces. The power package moreover includes where the at least one signal trace may include a plurality of implementations of the at least one signal trace. The power package also includes where the plurality of implementations of the at least one signal trace may include a plurality of kelvin source traces and/or gate traces. The power package further includes where the at least one power trace may include one or more power device drain traces and/or power device source traces. The power package in addition includes where the at least one power trace may include a plurality of power traces having a plurality of power device drain traces and/or power device source traces. The power package moreover includes where the first power terminals and the second power terminals are configured to connect to the at least one power trace. The power package also includes where the first signal terminals and the second signal terminals are configured to connect to the at least one signal trace. The power package further includes may include a plurality of power devices, where the plurality of power devices are arranged on one or more implementations of the at least one power trace. The power package in addition includes where a location of the plurality of power devices, the at least one signal trace, the at least one power trace, and/or the power substrate are symmetrical about a lateral axis of symmetry. The power package moreover includes where a location of the plurality of power devices, the at least one signal trace, the at least one power trace, and/or the power substrate are symmetrical about a longitudinal axis of symmetry. The power package also includes where the first power terminals are configured to connect to respective first power connections of an application; where the second power terminals are configured to connect to respective second power connections of an application; where the plurality of power devices, the at least one signal trace, the at least one power trace, and/or the power substrate are configured to operate in a manner when the first power terminals connect to the respective first power connections and the second power terminals connect to the respective second power connections; and where the plurality of power devices, the at least one signal trace, the at least one power trace, and/or the power substrate are configured to operate in a same manner when the first power terminals connect to the respective second power connections and the second power terminals connect to the respective first power connections. The power package further includes where the plurality of power devices may include at least one first power device and at least one second power device; where the at least one power trace may include a first power trace, a second power trace, a third power trace, and a fourth power trace; where the at least one first power device is arranged on and attached to the second power trace; and where the at least one second power device is arranged on and attached to the third power trace. The power package in addition includes where the first power terminals, the second power terminals, the first signal terminals, the second signal terminals, the plurality of power devices, the at least one signal trace, the at least one power trace, and/or the power substrate are configured, structured, arranged, and/or implemented such that the power package implements a standalone configuration, a paralleled configuration, a common-source bidirectional configuration, and/or a common-drain bidirectional configuration. The power package moreover includes where the first power terminals may include a first power terminal, a second power terminal, a third power terminal, and a fourth power terminal; and where the second power terminals may include a first power terminal, a second power terminal, a third power terminal, and a fourth power terminal. The power package also includes where the first signal terminals may include a first signal terminal, a second signal terminal, and a third signal terminal; and where the second signal terminals may include a first signal terminal, a second signal terminal, and a third signal terminal. The power package further includes may include at least a first power package portion and a second power package portion, where the first power package portion may include the first signal terminals; where the first power package portion further may include interconnection power terminals; where the second power package portion may include the second signal terminals; and where the second power package portion further may include interconnection power terminals. The power package in addition includes where the interconnection power terminals of the first power package portion are configured to connect to the interconnection power terminals of the second power package portion. The power package moreover includes where the interconnection power terminals of the first power package portion and the interconnection power terminals of the second power package portion may include common source terminals. The power package also includes where the interconnection power terminals of the first power package portion and the interconnection power terminals of the second power package portion may include common drain terminals.

One EXAMPLE: a process includes providing an assembly with a first power package side and a second power package side. The process also includes arranging first power terminals at the first power package side. The process furthermore includes arranging second power terminals at the second power package side. The process in addition includes arranging first signal terminals at the first power package side. The process moreover includes arranging second signal terminals arranged at the second power package side. The process also includes where a location of the first power terminals on the first power package side is symmetrical with respect to a location of the second power terminals on the second power package side.

The above-noted EXAMPLE may further include any one or a combination of more than one of the following EXAMPLES:

The process includes where a location of the first power terminals on the first power package side is symmetrical with respect to one side of the first power package side and another side of the first power package side; and where a location of the second power terminals on the second power package side is symmetrical with respect to one side of the second power package side and another side of the second power package side. The process also includes where a location of the first signal terminals on the first power package side is symmetrical with respect to a location of the second signal terminals on the second power package side. The process further includes where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The process in addition includes where a location of the first signal terminals on the first power package side is symmetrical with respect to a location of the second signal terminals on the second power package side; where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The process moreover includes where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The process also includes where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections. The process further includes where the first signal terminals may include one or more source kelvin terminals, gate terminals, and/or sensor terminals; and where the second signal terminals may include one or more source kelvin terminals, gate terminals, and/or sensor terminals. The process in addition includes where the first signal terminals are arranged on the first power package side between implementations of the first power terminals; and where the second signal terminals are arranged on the second power package side between implementations of the second power terminals. The process moreover includes where the first power terminals are arranged on the first power package side between implementations of the first signal terminals; and where the second power terminals are arranged on the second power package side between implementations of the second signal terminals. The process also includes may include: providing a power substrate; arranging at least one power trace on the power substrate; and arranging at least one signal trace on the power substrate. The process further includes where the at least one power trace may include a plurality of implementations of the at least one power trace. The process in addition includes where the at least one signal trace may include one or more kelvin source traces, gate traces, and/or sensor traces. The process moreover includes where the at least one signal trace may include a plurality of implementations of the at least one signal trace. The process also includes where the plurality of implementations of the at least one signal trace may include a plurality of kelvin source traces and/or gate traces. The process further includes where the at least one power trace may include one or more power device drain traces and/or power device source traces. The process in addition includes where the at least one power trace may include a plurality of power traces having a plurality of power device drain traces and/or power device source traces. The process moreover includes where the first power terminals and the second power terminals are configured to connect to the at least one power trace. The process also includes where the first signal terminals and the second signal terminals are configured to connect to the at least one signal trace. The process further includes may include arranging a plurality of power devices on one or more implementations of the at least one power trace. The process in addition includes where a location of the plurality of power devices, the at least one signal trace, the at least one power trace, and/or the power substrate are symmetrical about a lateral axis of symmetry. The process moreover includes where a location of the plurality of power devices, the at least one signal trace, the at least one power trace, and/or the power substrate are symmetrical about a longitudinal axis of symmetry. The process also includes where the first power terminals are configured to connect to respective first power connections of an application; where the second power terminals are configured to connect to respective second power connections of an application; where the plurality of power devices, the at least one signal trace, the at least one power trace, and/or the power substrate are configured to operate in a manner when the first power terminals connect to the respective first power connections and the second power terminals connect to the respective second power connections; and where the plurality of power devices, the at least one signal trace, the at least one power trace, and/or the power substrate are configured to operate in a same manner when the first power terminals connect to the respective second power connections and the second power terminals connect to the respective first power connections. The process further includes where the plurality of power devices may include at least one first power device and at least one second power device; where the at least one power trace may include a first power trace, a second power trace, a third power trace, and a fourth power trace; where the at least one first power device is arranged on and attached to the second power trace; and where the at least one second power device is arranged on and attached to the third power trace. The process in addition includes where the first power terminals, the second power terminals, the first signal terminals, the second signal terminals, the plurality of power devices, the at least one signal trace, the at least one power trace, and/or the power substrate are configured, structured, arranged, and/or implemented such that the power package implements a standalone configuration, a paralleled configuration, a common-source bidirectional configuration, and/or a common-drain bidirectional configuration. The process moreover includes where the first power terminals may include a first power terminal, a second power terminal, a third power terminal, and a fourth power terminal; and where the second power terminals may include a first power terminal, a second power terminal, a third power terminal, and a fourth power terminal. The process also includes where the first signal terminals may include a first signal terminal, a second signal terminal, and a third signal terminal; and where the second signal terminals may include a first signal terminal, a second signal terminal, and a third signal terminal. The process further includes may include providing at least a first power package portion and a second power package portion, where the first power package portion may include the first power terminals; where the first power package portion further may include interconnection power terminals; where the second power package portion may include the second power terminals; and where the second power package portion further may include interconnection power terminals. The process in addition includes where the interconnection power terminals of the first power package portion are configured to connect to the interconnection power terminals of the second power package portion. The process moreover includes where the interconnection power terminals of the first power package portion and the interconnection power terminals of the second power package portion may include common source terminals. The process also includes where the interconnection power terminals of the first power package portion and the interconnection power terminals of the second power package portion may include common drain terminals.

One EXAMPLE: a process includes providing an assembly with a first power package side and a second power package side. The process also includes arranging first power terminals at the first power package side. The process furthermore includes arranging second power terminals at the second power package side. The process in addition includes arranging first signal terminals at the first power package side. The process moreover includes arranging second signal terminals arranged at the second power package side. The process also includes where a location of the first power terminals on the first power package side is symmetrical with respect to one side of the first power package side and another side of the first power package side. The process furthermore includes where a location of the second power terminals on the second power package side is symmetrical with respect to one side of the second power package side and another side of the second power package side.

The above-noted EXAMPLE may further include any one or a combination of more than one of the following EXAMPLES:

The process includes where a location of the first power terminals on the first power package side is symmetrical with respect to a location of the second power terminals on the second power package side. The process also includes where a location of the first signal terminals on the first power package side is symmetrical with respect to a location of the second signal terminals on the second power package side. The process further includes where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The process in addition includes where a location of the first signal terminals on the first power package side is symmetrical with respect to a location of the second signal terminals on the second power package side; and where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The process moreover includes where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The process also includes where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections. The process further includes where the first signal terminals may include one or more source kelvin terminals, gate terminals, and/or sensor terminals; and where the second signal terminals may include one or more source kelvin terminals, gate terminals, and/or sensor terminals. The process in addition includes where the first signal terminals are arranged on the first power package side between implementations of the first power terminals; and where the second signal terminals are arranged on the second power package side between implementations of the second power terminals. The process moreover includes where the first power terminals are arranged on the first power package side between implementations of the first signal terminals; and where the second power terminals are arranged on the second power package side between implementations of the second signal terminals. The process also includes may include: providing a power substrate; arranging at least one power trace on the power substrate; and arranging at least one signal trace on the power substrate. The process further includes where the at least one power trace may include a plurality of implementations of the at least one power trace. The process in addition includes where the at least one signal trace may include one or more kelvin source traces, gate traces, and/or sensor traces. The process moreover includes where the at least one signal trace may include a plurality of implementations of the at least one signal trace. The process also includes where the plurality of implementations of the at least one signal trace may include a plurality of kelvin source traces and/or gate traces. The process further includes where the at least one power trace may include one or more power device drain traces and/or power device source traces. The process in addition includes where the at least one power trace may include a plurality of power traces having a plurality of power device drain traces and/or power device source traces. The process moreover includes where the first power terminals and the second power terminals are configured to connect to the at least one power trace. The process also includes where the first signal terminals and the second signal terminals are configured to connect to the at least one signal trace. The process further includes may include arranging a plurality of power devices on one or more implementations of the at least one power trace. The process in addition includes where a location of the plurality of power devices, the at least one signal trace, the at least one power trace, and/or the power substrate are symmetrical about a lateral axis of symmetry. The process moreover includes where a location of the plurality of power devices, the at least one signal trace, the at least one power trace, and/or the power substrate are symmetrical about a longitudinal axis of symmetry. The process also includes where the first power terminals are configured to connect to respective first power connections of an application; where the second power terminals are configured to connect to respective second power connections of an application; where the plurality of power devices, the at least one signal trace, the at least one power trace, and/or the power substrate are configured to operate in a manner when the first power terminals connect to the respective first power connections and the second power terminals connect to the respective second power connections; and where the plurality of power devices, the at least one signal trace, the at least one power trace, and/or the power substrate are configured to operate in a same manner when the first power terminals connect to the respective second power connections and the second power terminals connect to the respective first power connections. The process further includes where the plurality of power devices may include at least one first power device and at least one second power device; where the at least one power trace may include a first power trace, a second power trace, a third power trace, and a fourth power trace; where the at least one first power device is arranged on and attached to the second power trace; and where the at least one second power device is arranged on and attached to the third power trace. The process in addition includes where the first power terminals, the second power terminals, the first signal terminals, the second signal terminals, the plurality of power devices, the at least one signal trace, the at least one power trace, and/or the power substrate are configured, structured, arranged, and/or implemented such that the power package implements a standalone configuration, a paralleled configuration, a common-source bidirectional configuration, and/or a common-drain bidirectional configuration. The process moreover includes where the first power terminals may include a first power terminal, a second power terminal, a third power terminal, and a fourth power terminal; and where the second power terminals may include a first power terminal, a second power terminal, a third power terminal, and a fourth power terminal. The process also includes where the first signal terminals may include a first signal terminal, a second signal terminal, and a third signal terminal; and where the second signal terminals may include a first signal terminal, a second signal terminal, and a third signal terminal. The process further includes may include providing at least a first power package portion and a second power package portion, where the first power package portion may include the first power terminals; where the first power package portion further may include interconnection power terminals; where the second power package portion may include the second power terminals; and where the second power package portion further may include interconnection power terminals. The process in addition includes where the interconnection power terminals of the first power package portion are configured to connect to the interconnection power terminals of the second power package portion. The process moreover includes where the interconnection power terminals of the first power package portion and the interconnection power terminals of the second power package portion may include common source terminals. The process also includes where the interconnection power terminals of the first power package portion and the interconnection power terminals of the second power package portion may include common drain terminals.

One EXAMPLE: a process includes providing an assembly with a first power package side and a second power package side. The process also includes arranging first power terminals at the first power package side. The process furthermore includes arranging second power terminals at the second power package side. The process in addition includes arranging first signal terminals at the first power package side. The process moreover includes arranging second signal terminals arranged at the second power package side. The process also includes where a location of the first signal terminals on the first power package side is symmetrical with respect to one side of the first power package side and another side of the first power package side. The process furthermore includes where a location of the second signal terminals on the second power package side is symmetrical with respect to one side of the second power package side and another side of the second power package side.

The above-noted EXAMPLE may further include any one or a combination of more than one of the following EXAMPLES:

The process includes where a location of the first power terminals on the first power package side is symmetrical with respect to a location of the second power terminals on the second power package side. The process also includes where a location of the first signal terminals on the first power package side is symmetrical with respect to a location of the second signal terminals on the second power package side. The process further includes where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The process in addition includes where a location of the first power terminals is symmetrical about a longitudinal axis of symmetry with respect to a location of the second power terminals; and where a location of the first power terminals on the first power package side is symmetrical with respect to a location of the second power terminals on the second power package side. The process moreover includes where a location of the first signal terminals on the first power package side is symmetrical with respect to a location of the second signal terminals on the second power package side; and where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The process also includes where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The process further includes where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections. The process in addition includes where the first signal terminals may include one or more source kelvin terminals, gate terminals, and/or sensor terminals; and where the second signal terminals may include one or more source kelvin terminals, gate terminals, and/or sensor terminals. The process moreover includes where the first signal terminals are arranged on the first power package side between implementations of the first power terminals; and where the second signal terminals are arranged on the second power package side between implementations of the second power terminals. The process also includes where the first power terminals are arranged on the first power package side between implementations of the first signal terminals; and where the second power terminals are arranged on the second power package side between implementations of the second signal terminals. The process further includes may include: providing a power substrate; arranging at least one power trace on the power substrate; and arranging at least one signal trace on the power substrate. The process in addition includes where the at least one power trace may include a plurality of implementations of the at least one power trace. The process moreover includes where the at least one signal trace may include one or more kelvin source traces, gate traces, and/or sensor traces. The process also includes where the at least one signal trace may include a plurality of implementations of the at least one signal trace. The process further includes where the plurality of implementations of the at least one signal trace may include a plurality of kelvin source traces and/or gate traces. The process in addition includes where the at least one power trace may include one or more power device drain traces and/or power device source traces. The process moreover includes where the at least one power trace may include a plurality of power traces having a plurality of power device drain traces and/or power device source traces. The process also includes where the first power terminals and the second power terminals are configured to connect to the at least one power trace. The process further includes where the first signal terminals and the second signal terminals are configured to connect to the at least one signal trace. The process in addition includes may include arranging a plurality of power devices on one or more implementations of the at least one power trace. The process moreover includes where a location of the plurality of power devices, the at least one signal trace, the at least one power trace, and/or the power substrate are symmetrical about a lateral axis of symmetry. The process also includes where a location of the plurality of power devices, the at least one signal trace, the at least one power trace, and/or the power substrate are symmetrical about a longitudinal axis of symmetry. The process further includes where the first power terminals are configured to connect to respective first power connections of an application; where the second power terminals are configured to connect to respective second power connections of an application; where the plurality of power devices, the at least one signal trace, the at least one power trace, and/or the power substrate are configured to operate in a manner when the first power terminals connect to the respective first power connections and the second power terminals connect to the respective second power connections; and where the plurality of power devices, the at least one signal trace, the at least one power trace, and/or the power substrate are configured to operate in a same manner when the first power terminals connect to the respective second power connections and the second power terminals connect to the respective first power connections. The process in addition includes where the plurality of power devices may include at least one first power device and at least one second power device; where the at least one power trace may include a first power trace, a second power trace, a third power trace, and a fourth power trace; where the at least one first power device is arranged on and attached to the second power trace; and where the at least one second power device is arranged on and attached to the third power trace. The process moreover includes where the first power terminals, the second power terminals, the first signal terminals, the second signal terminals, the plurality of power devices, the at least one signal trace, the at least one power trace, and/or the power substrate are configured, structured, arranged, and/or implemented such that the power package implements a standalone configuration, a paralleled configuration, a common-source bidirectional configuration, and/or a common-drain bidirectional configuration. The process also includes where the first power terminals may include a first power terminal, a second power terminal, a third power terminal, and a fourth power terminal; and where the second power terminals may include a first power terminal, a second power terminal, a third power terminal, and a fourth power terminal. The process further includes where the first signal terminals may include a first signal terminal, a second signal terminal, and a third signal terminal; and where the second signal terminals may include a first signal terminal, a second signal terminal, and a third signal terminal. The process in addition includes may include providing at least a first power package portion and a second power package portion, where the first power package portion may include the first signal terminals; where the first power package portion further may include interconnection power terminals; where the second power package portion may include the second signal terminals; and where the second power package portion further may include interconnection power terminals. The process moreover includes where the interconnection power terminals of the first power package portion are configured to connect to the interconnection power terminals of the second power package portion. The process also includes where the interconnection power terminals of the first power package portion and the interconnection power terminals of the second power package portion may include common source terminals. The process further includes where the interconnection power terminals of the first power package portion and the interconnection power terminals of the second power package portion may include common drain terminals.

One EXAMPLE: a process includes providing an assembly with a first power package side and a second power package side. The process also includes arranging first power terminals at the first power package side. The process furthermore includes arranging second power terminals at the second power package side. The process in addition includes arranging first signal terminals at the first power package side. The process moreover includes arranging second signal terminals arranged at the second power package side. The process also includes where a location of the first signal terminals on the first power package side is symmetrical with respect to a location of the second signal terminals on the second power package side.

The above-noted EXAMPLE may further include any one or a combination of more than one of the following EXAMPLES:

The process includes where a location of the first power terminals on the first power package side is symmetrical with respect to one side of the first power package side and another side of the first power package side; and where a location of the second power terminals on the second power package side is symmetrical with respect to one side of the second power package side and another side of the second power package side. The process also includes where a location of the first power terminals on the first power package side is symmetrical with respect to a location of the second power terminals on the second power package side. The process further includes where a location of the first signal terminals on the first power package side is symmetrical with respect to one side of the first power package side and another side of the first power package side; and where a location of the second signal terminals on the second power package side is symmetrical with respect to one side of the second power package side and another side of the second power package side. The process in addition includes where a location of the first power terminals on the first power package side is symmetrical with respect to a location of the second power terminals on the second power package side; where a location of the first power terminals on the first power package side is symmetrical with respect to one side of the first power package side and another side of the first power package side; and where a location of the second power terminals on the second power package side is symmetrical with respect to one side of the second power package side and another side of the second power package side. The process moreover includes where the first power terminals are configured to connect to respective first power connections of an application; where the second power terminals are configured to connect to respective second power connections of an application; where the power package is configured to operate in a manner when the first power terminals connect to the respective first power connections and the second power terminals connect to the respective second power connections of the application; and where the power package is configured to operate in a same manner when the first power terminals connect to the respective second power connections and the second power terminals connect to the respective first power connections. The process also includes where the first signal terminals are configured to connect to respective first signal connections to an application; where the second signal terminals are configured to connect to respective second signal connections to an application; and where the power package is configured to operate in a manner when the first signal terminals connect to the respective first signal connections and the second signal terminals connect to the respective second signal connections of the application; and where the power package is configured to operate in a same manner when the first signal terminals connect to the respective second signal connections and the second signal terminals connect to the respective first signal connections. The process further includes where the first signal terminals may include one or more source kelvin terminals, gate terminals, and/or sensor terminals; and where the second signal terminals may include one or more source kelvin terminals, gate terminals, and/or sensor terminals. The process in addition includes where the first signal terminals are arranged on the first power package side between implementations of the first power terminals; and where the second signal terminals are arranged on the second power package side between implementations of the second power terminals. The process moreover includes where the first power terminals are arranged on the first power package side between implementations of the first signal terminals; and where the second power terminals are arranged on the second power package side between implementations of the second signal terminals. The process also includes may include: providing a power substrate; arranging at least one power trace on the power substrate; and arranging at least one signal trace on the power substrate. The process further includes where the at least one power trace may include a plurality of implementations of the at least one power trace. The process in addition includes where the at least one signal trace may include one or more kelvin source traces, gate traces, and/or sensor traces. The process moreover includes where the at least one signal trace may include a plurality of implementations of the at least one signal trace. The process also includes where the plurality of implementations of the at least one signal trace may include a plurality of kelvin source traces and/or gate traces. The process further includes where the at least one power trace may include one or more power device drain traces and/or power device source traces. The process in addition includes where the at least one power trace may include a plurality of power traces having a plurality of power device drain traces and/or power device source traces. The process moreover includes where the first power terminals and the second power terminals are configured to connect to the at least one power trace. The process also includes where the first signal terminals and the second signal terminals are configured to connect to the at least one signal trace. The process further includes may include arranging a plurality of power devices on one or more implementations of the at least one power trace. The process in addition includes where a location of the plurality of power devices, the at least one signal trace, the at least one power trace, and/or the power substrate are symmetrical about a lateral axis of symmetry. The process moreover includes where a location of the plurality of power devices, the at least one signal trace, the at least one power trace, and/or the power substrate are symmetrical about a longitudinal axis of symmetry. The process also includes where the first power terminals are configured to connect to respective first power connections of an application; where the second power terminals are configured to connect to respective second power connections of an application; where the plurality of power devices, the at least one signal trace, the at least one power trace, and/or the power substrate are configured to operate in a manner when the first power terminals connect to the respective first power connections and the second power terminals connect to the respective second power connections; and where the plurality of power devices, the at least one signal trace, the at least one power trace, and/or the power substrate are configured to operate in a same manner when the first power terminals connect to the respective second power connections and the second power terminals connect to the respective first power connections. The process further includes where the plurality of power devices may include at least one first power device and at least one second power device; where the at least one power trace may include a first power trace, a second power trace, a third power trace, and a fourth power trace; where the at least one first power device is arranged on and attached to the second power trace; and where the at least one second power device is arranged on and attached to the third power trace. The process in addition includes where the first power terminals, the second power terminals, the first signal terminals, the second signal terminals, the plurality of power devices, the at least one signal trace, the at least one power trace, and/or the power substrate are configured, structured, arranged, and/or implemented such that the power package implements a standalone configuration, a paralleled configuration, a common-source bidirectional configuration, and/or a common-drain bidirectional configuration. The process moreover includes where the first power terminals may include a first power terminal, a second power terminal, a third power terminal, and a fourth power terminal; and where the second power terminals may include a first power terminal, a second power terminal, a third power terminal, and a fourth power terminal. The process also includes where the first signal terminals may include a first signal terminal, a second signal terminal, and a third signal terminal; and where the second signal terminals may include a first signal terminal, a second signal terminal, and a third signal terminal. The process further includes may include providing at least a first power package portion and a second power package portion, where the first power package portion may include the first signal terminals; where the first power package portion further may include interconnection power terminals; where the second power package portion may include the second signal terminals; and where the second power package portion further may include interconnection power terminals. The process in addition includes where the interconnection power terminals of the first power package portion are configured to connect to the interconnection power terminals of the second power package portion. The process moreover includes where the interconnection power terminals of the first power package portion and the interconnection power terminals of the second power package portion may include common source terminals. The process also includes where the interconnection power terminals of the first power package portion and the interconnection power terminals of the second power package portion may include common drain terminals.

One EXAMPLE: a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where an arrangement and location of the first power terminals is symmetrical about a lateral axis of symmetry with respect to an arrangement and location of the second power terminals.

The above-noted EXAMPLE may further include any one or a combination of more than one of the following EXAMPLES:

The power package includes where an arrangement and location of the first power terminals is symmetrical about a longitudinal axis of symmetry with respect to an arrangement and location of the second power terminals. The power package also includes where an arrangement and location of the first signal terminals is symmetrical about the lateral axis of symmetry with respect to an arrangement and location of the second signal terminals. The power package further includes where an arrangement and location of the first signal terminals is symmetrical about a longitudinal axis of symmetry with respect to an arrangement and location of the second signal terminals. The power package in addition includes where an arrangement and location of the first power terminals is symmetrical about a longitudinal axis of symmetry with respect to an arrangement and location of the second power terminals; and where an arrangement and location of the first power terminals is symmetrical about the lateral axis of symmetry with respect to an arrangement and location of the second power terminals. The power package moreover includes where an arrangement and location of the first signal terminals is symmetrical about a longitudinal axis of symmetry with respect to an arrangement and location of the second signal terminals; and where an arrangement and location of the first signal terminals is symmetrical about the lateral axis of symmetry with respect to an arrangement and location of the second signal terminals.

One EXAMPLE: a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where an arrangement and location of the first power terminals is symmetrical about a longitudinal axis of symmetry with respect to an arrangement and location of the second power terminals.

The above-noted EXAMPLE may further include any one or a combination of more than one of the following EXAMPLES:

The power package includes where an arrangement and location of the first power terminals is symmetrical about a lateral axis of symmetry with respect to an arrangement and location of the second power terminals. The power package also includes where an arrangement and location of the first signal terminals is symmetrical about a lateral axis of symmetry with respect to an arrangement and location of the second signal terminals. The power package further includes where an arrangement and location of the first signal terminals is symmetrical about the longitudinal axis of symmetry with respect to an arrangement and location of the second signal terminals. The power package in addition includes where an arrangement and location of the first power terminals is symmetrical about the longitudinal axis of symmetry with respect to an arrangement and location of the second power terminals; and where an arrangement and location of the first power terminals is symmetrical about a lateral axis of symmetry with respect to an arrangement and location of the second power terminals. The power package moreover includes where an arrangement and location of the first signal terminals is symmetrical about the longitudinal axis of symmetry with respect to an arrangement and location of the second signal terminals; and where an arrangement and location of the first signal terminals is symmetrical about a lateral axis of symmetry with respect to an arrangement and location of the second signal terminals.

One EXAMPLE: a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where an arrangement and location of the first signal terminals is symmetrical about a longitudinal axis of symmetry with respect to an arrangement and location of the second signal terminals.

The above-noted EXAMPLE may further include any one or a combination of more than one of the following EXAMPLES:

The power package includes where an arrangement and location of the first power terminals is symmetrical about a lateral axis of symmetry with respect to an arrangement and location of the second power terminals. The power package also includes where an arrangement and location of the first signal terminals is symmetrical about a lateral axis of symmetry with respect to an arrangement and location of the second signal terminals. The power package further includes where an arrangement and location of the first power terminals is symmetrical about the longitudinal axis of symmetry with respect to an arrangement and location of the second power terminals. The power package in addition includes where an arrangement and location of the first power terminals is symmetrical about the longitudinal axis of symmetry with respect to an arrangement and location of the second power terminals; and where an arrangement and location of the first power terminals is symmetrical about a lateral axis of symmetry with respect to an arrangement and location of the second power terminals. The power package moreover includes where an arrangement and location of the first signal terminals is symmetrical about the longitudinal axis of symmetry with respect to an arrangement and location of the second signal terminals; and where an arrangement and location of the first signal terminals is symmetrical about a lateral axis of symmetry with respect to an arrangement and location of the second signal terminals.

One EXAMPLE: a power package includes an assembly having a first power package side and a second power package side. The power package also includes first power terminals arranged at the first power package side. The power package furthermore includes second power terminals arranged at the second power package side. The power package in addition includes first signal terminals arranged at the first power package side. The power package moreover includes second signal terminals arranged at the second power package side. The power package also includes where an arrangement and location of the first signal terminals is symmetrical about a lateral axis of symmetry with respect to an arrangement and location of the second signal terminals.

The above-noted EXAMPLE may further include any one or a combination of more than one of the following EXAMPLES:

The power package includes where an arrangement and location of the first power terminals is symmetrical about a longitudinal axis of symmetry with respect to an arrangement and location of the second power terminals. The power package also includes where an arrangement and location of the first power terminals is symmetrical about a lateral axis of symmetry with respect to an arrangement and location of the second power terminals. The power package further includes where an arrangement and location of the first signal terminals is symmetrical about a longitudinal axis of symmetry with respect to an arrangement and location of the second signal terminals. The power package in addition includes where an arrangement and location of the first power terminals is symmetrical about a longitudinal axis of symmetry with respect to an arrangement and location of the second power terminals; and where an arrangement and location of the first power terminals is symmetrical about the lateral axis of symmetry with respect to an arrangement and location of the second power terminals. The power package moreover includes where an arrangement and location of the first signal terminals is symmetrical about a longitudinal axis of symmetry with respect to an arrangement and location of the second signal terminals; and where an arrangement and location of the first signal terminals is symmetrical about the lateral axis of symmetry with respect to an arrangement and location of the second signal terminals.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a solid mass of material by heat and/or pressure. The sintering process may operate without melting the material to the point of liquefaction. The sintering process may include sintering of metallic powders. The sintering process may include sintering in a vacuum. The sintering process may include sintering with the use of a protective gas.

The eutectic bonding of the disclosure may utilize a bonding process with an intermediate metal layer that may form a eutectic system. The eutectic system may be used between surfaces to be connected. The eutectic bonding may utilize eutectic metals that may be alloys that transform from solid to liquid state, or from liquid to solid state, at a specific composition and temperature without passing a two-phase equilibrium. The eutectic alloys may be deposited by sputtering, dual source evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A power package comprising:
an assembly comprising a first power package side and a second power package side;
first power terminals arranged at the first power package side;
second power terminals arranged at the second power package side;
first signal terminals arranged at the first power package side; and
second signal terminals arranged at the second power package side,
wherein a location of the first power terminals on the first power package side is symmetrical with respect to a location of the second power terminals on the second power package side.

2. The power package according to claim 1,
wherein a location of the first power terminals on the first power package side is symmetrical with respect to one side of the first power package side and another side of the first power package side; and
wherein a location of the second power terminals on the second power package side is symmetrical with respect to one side of the second power package side and another side of the second power package side.

3. The power package according to claim 1, wherein a location of the first signal terminals on the first power package side is symmetrical with respect to a location of the second signal terminals on the second power package side.

4. The power package according to claim 1,
wherein a location of the first signal terminals on the first power package side is symmetrical with respect to one side of the first power package side and another side of the first power package side; and
wherein a location of the second signal terminals on the second power package side is symmetrical with respect to one side of the second power package side and another side of the second power package side.

5. The power package according to claim 1,
wherein the first power terminals are configured to connect to respective first power connections of an application;
wherein the second power terminals are configured to connect to respective second power connections of an application;
wherein the power package is configured to operate in a manner when the first power terminals connect to the respective first power connections and the second power terminals connect to the respective second power connections of the application; and
wherein the power package is configured to operate in a same manner when the first power terminals connect to the respective second power connections and the second power terminals connect to the respective first power connections.

6. The power package according to claim 1,
wherein the first signal terminals are configured to connect to respective first signal connections to an application;
wherein the second signal terminals are configured to connect to respective second signal connections to an application; and
wherein the power package is configured to operate in a manner when the first signal terminals connect to the respective first signal connections and the second signal terminals connect to the respective second signal connections of the application; and
wherein the power package is configured to operate in a same manner when the first signal terminals connect to the respective second signal connections and the second signal terminals connect to the respective first signal connections.

7. The power package according to claim 1,
wherein the first signal terminals comprise one or more source kelvin terminals, gate terminals, and/or sensor terminals; and
wherein the second signal terminals comprise one or more source kelvin terminals, gate terminals, and/or sensor terminals.

8. The power package according to claim 1,
wherein the first signal terminals are arranged on the first power package side between implementations of the first power terminals; and
wherein the second signal terminals are arranged on the second power package side between implementations of the second power terminals.

9. The power package according to claim 1,
wherein the first power terminals are arranged on the first power package side between implementations of the first signal terminals; and
wherein the second power terminals are arranged on the second power package side between implementations of the second signal terminals.

10. The power package according to claim 1, further comprising:
a power substrate;
at least one power trace arranged on the power substrate; and
at least one signal trace arranged on the power substrate.

11. The power package according to claim 10, wherein the at least one power trace comprises a plurality of implementations of the at least one power trace.

12. The power package according to claim 10, wherein the at least one signal trace comprises one or more kelvin source traces, gate traces, and/or sensor traces.

13. The power package according to claim 10, wherein the at least one signal trace comprises a plurality of implementations of the at least one signal trace.

14. The power package according to claim 13, wherein the plurality of implementations of the at least one signal trace comprise a plurality of kelvin source traces and/or gate traces.

15. The power package according to claim 10, wherein the at least one power trace comprises one or more power device drain traces and/or power device source traces.

16. The power package according to claim 10, wherein the at least one power trace comprises a plurality of power traces comprising a plurality of power device drain traces and/or power device source traces.

17. The power package according to claim 10, wherein the first power terminals and the second power terminals are configured to connect to the at least one power trace.

18. The power package according to claim 10, wherein the first signal terminals and the second signal terminals are configured to connect to the at least one signal trace.

19. The power package according to claim 10, further comprising a plurality of power devices,
wherein the plurality of power devices are arranged on one or more implementations of the at least one power trace.

20. The power package according to claim 19, wherein a location of the plurality of power devices, the at least one signal trace, the at least one power trace, and/or the power substrate are symmetrical about a lateral axis of symmetry.

21. The power package according to claim 19, wherein a location of the plurality of power devices, the at least one signal trace, the at least one power trace, and/or the power substrate are symmetrical about a longitudinal axis of symmetry.

22. The power package according to claim 19,
wherein the first power terminals are configured to connect to respective first power connections of an application;
wherein the second power terminals are configured to connect to respective second power connections of an application;
wherein the plurality of power devices, the at least one signal trace, the at least one power trace, and/or the power substrate are configured to operate in a manner when the first power terminals connect to the respective first power connections and the second power terminals connect to the respective second power connections; and
wherein the plurality of power devices, the at least one signal trace, the at least one power trace, and/or the power substrate are configured to operate in a same manner when the first power terminals connect to the respective second power connections and the second power terminals connect to the respective first power connections.

23. The power package according to claim 19,
wherein the plurality of power devices comprise at least one first power device and at least one second power device;
wherein the at least one power trace comprises a first power trace, a second power trace, a third power trace, and a fourth power trace;
wherein the at least one first power device is arranged on and attached to the second power trace; and
wherein the at least one second power device is arranged on and attached to the third power trace.

24. The power package according to claim 1,
wherein the first power terminals comprise a first power terminal, a second power terminal, a third power terminal, and a fourth power terminal; and
wherein the second power terminals comprise a first power terminal, a second power terminal, a third power terminal, and a fourth power terminal.

25. The power package according to claim 1,
wherein the first signal terminals comprise a first signal terminal, a second signal terminal, and a third signal terminal; and
wherein the second signal terminals comprise a first signal terminal, a second signal terminal, and a third signal terminal.

26. (canceled)

27. The power package according to claim 1, further comprising at least a first power package portion and a second power package portion,
wherein the first power package portion comprises the first power terminals;
wherein the first power package portion further comprises interconnection power terminals;
wherein the second power package portion comprises the second power terminals; and
wherein the second power package portion further comprises interconnection power terminals.

28. The power package according to claim 27, wherein the interconnection power terminals of the first power package portion are configured to connect to the interconnection power terminals of the second power package portion.

29. The power package according to claim 27, wherein the interconnection power terminals of the first power package portion and the interconnection power terminals of the second power package portion comprise common source terminals.

30. The power package according to claim 27, wherein the interconnection power terminals of the first power package portion and the interconnection power terminals of the second power package portion comprise common drain terminals.

31. The power package according to claim 1, wherein the power package is a power module.

32. A power package comprising:
an assembly comprising a first power package side and a second power package side;
first power terminals arranged at the first power package side;
second power terminals arranged at the second power package side;
first signal terminals arranged at the first power package side; and
second signal terminals arranged at the second power package side,
wherein a location of the first signal terminals on the first power package side is symmetrical with respect to a location of the second signal terminals on the second power package side.

33.-284. (canceled)
